(19) United States
(12) Patent Application Publication
(10) Pub. No.: US 2024/0332248 A1
(43) Pub. Date: Oct. 3, 2024

(54) DIRECT HYBRID BONDING IN TOPOGRAPHIC PACKAGES

(71) Applicant: ADEIA SEMICONDUCTOR BONDING TECHNOLOGIES INC., San Jose, CA (US)

(72) Inventor: Cyprian Emeka Uzoh, San Jose, CA (US)

(21) Appl. No.: 18/194,571

(22) Filed: Mar. 31, 2023

(51) Int. Cl. H01L 23/00; H01L 21/02; H01L 21/311; H01L 21/56; H01L 21/768; H01L 23/31; H01L 23/498; H01L 25/065

(52) U.S. Cl. CPC H01L 24/83; H01L 21/0228; H01L 21/31111; H01L 21/31144; H01L 21/56; H01L 21/76802; H01L 21/76831; H01L 21/76877; H01L 23/3135; H01L 23/49894; H01L 24/08; H01L 24/29; H01L 24/32; H01L 25/0652; H01L 2224/08146; H01L 2224/08225; H01L 2224/29187; H01L 2224/32145; H01L 2224/80895; H01L 2224/83896; H01L 2924/182

(57) ABSTRACT

Direct bond interconnect in topographic packages and methods of making. The topographic packages include a first die hybrid bonded to a substrate, the first die located in a first device level. A second die located in a second device level above the first device, the second die hybrid bonded to the first die. The topographic packages also include a third die located in a third device level above the second die, the third die hybrid bonded to a top surface of the second device level.

### BACKGROUND

### Field

The field relates to integrated circuit packages/integrated components having multiple dies.

### Description of the Related Art

Microelectronic assemblies generally include one or more integrated circuit (IC) dies (“chips”) which can be packaged for connection to an external device, such as a system board. One or more of such IC dies may be mounted on a circuit platform, such as a wafer for wafer-level-packaging (“WLP”), printed board (“PB”), a printed wiring board (“PWB”), a printed circuit board (“PCB”), a printed wiring assembly (“PWA”), a printed circuit assembly (“PCA”), a package substrate, an interposer, or a chip carrier. Additionally, one IC die may be mounted on another IC die. An interposer may be an IC die or other type of electronic component, and an interposer may be a passive or an active IC die, where the latter includes one or more active devices, such as transistors for example, and the former may or may not include any active or passive devices. Furthermore, an interposer may be formed like a PWB, namely without any circuit elements such as capacitors, resistors, or active devices. Additionally, an interposer can include at least one through-substrate-via.

The conventional method for fabricating IC packages is expensive. For example, the conventional method includes multiple dielectric layer depositions and multiple chemical mechanical polishing steps. The conventional method further includes long times for deep dielectric cavity etching and long times for deep cavity metal filling. All of these steps add cost to the process.

Accordingly, it would be desirable and useful to provide structures and methods for fabricating topographic packages, for example, topographic packages formed by direct hybrid bonding that addresses these problems.

### BRIEF DESCRIPTION OF THE DRAWINGS

Specific implementations will now be described with reference to the following drawings, which are provided by way of example, and not limitation.

FIGS. 1A-1P schematically illustrate cross-sectional views of a method of making example topographic packages according to some embodiments of the disclosed technology.

FIGS. 2A-2J schematically illustrate cross-sectional views of another method of making example topographic packages according to some embodiments of the disclosed technology.

FIGS. 3A-3G schematically illustrate cross-sectional views of another method of making example topographic packages according to some embodiments of the disclosed technology.

FIGS. 4A-4J schematically illustrate cross-sectional views of a method of making example topographic packages according to some embodiments of the disclosed technology.

FIGS. 5A-5O schematically illustrate cross-sectional views of a method of making example topographic packages according to some embodiments of the disclosed technology.

FIGS. 6A-6J schematically illustrate cross-sectional views of a method of making example topographic packages according to some embodiments of the disclosed technology.

FIGS. 7A and 7B are a process flow diagram illustrating a method of making example topographic packages according to some embodiments of the disclosed technology.

FIG. 8 is a process flow diagram illustrating another method of making example topographic packages according to some embodiments of the disclosed technology.

FIG. 9 is a process flow diagram illustrating another method of making example topographic packages according to some embodiments of the disclosed technology.

FIGS. 10A and 10B are a process flow diagram illustrating another method of making example topographic packages according to some embodiments of the disclosed technology.

FIGS. 11A and 11B are a process flow diagram illustrating another method of making example topographic packages according to some embodiments of the disclosed technology.

FIG. 12 schematically illustrates a cross-sectional view of an integrated circuit.

FIGS. 13A and 13B schematically illustrate a process for forming a directly hybrid bonded structure without an intervening adhesive according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The following description refers to topographic packages. Topographic packages include more than one semiconductor die located in different device levels. For example and as discussed in more detail below, topographic packages may include a second die located directly above a first die in the vertical direction, a third die located above the first and second dies in a vertical direction, second and/or third dies that are located above the first die in the vertical direction but only partially overlapping the first die in the horizontal direction and second and/or third dies that are located above the first die in the vertical direction but do not overlap the first die in the horizontal direction.

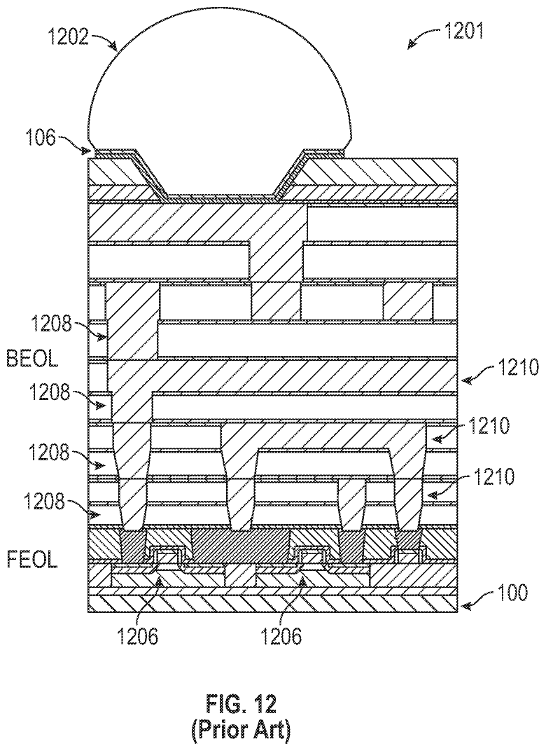

FIG. 12 illustrates a conventional integrated circuit 1201. The integrated circuit is fabricated on the front side a semiconducting wafer/substrate 100. In a first portion of fabrication, individual electrical components (e.g., transistors, resistors, capacitors) 1206 are formed. This first, device portion of fabrication is known as the front-end-of-line (FEOL). A second portion of the integrated circuit fabrication process, the back-end-of-line (BEOL) process is conducted, typically after the FEOL process is completed. The BEOL typically involves forming a stack of alternating dielectric and metallization layers during which interconnects 1210 and vias 1208 are formed. The interconnects comprise power lines which bring power to the and from the devices and signal lines which are used to get data from the devices. The signal lines may be broadly referred to as a signal distribution network (SDN) and the power lines as a power distribution network (PDN). Also included in the BEOL, is the formation of pads contact 106 for bonding the chip to a package or circuit board. The integrated circuit 1201 may also include a solder bump 1202 which allows for attachment of the integrated circuit 1201 to a circuit board or to another integrated circuit.

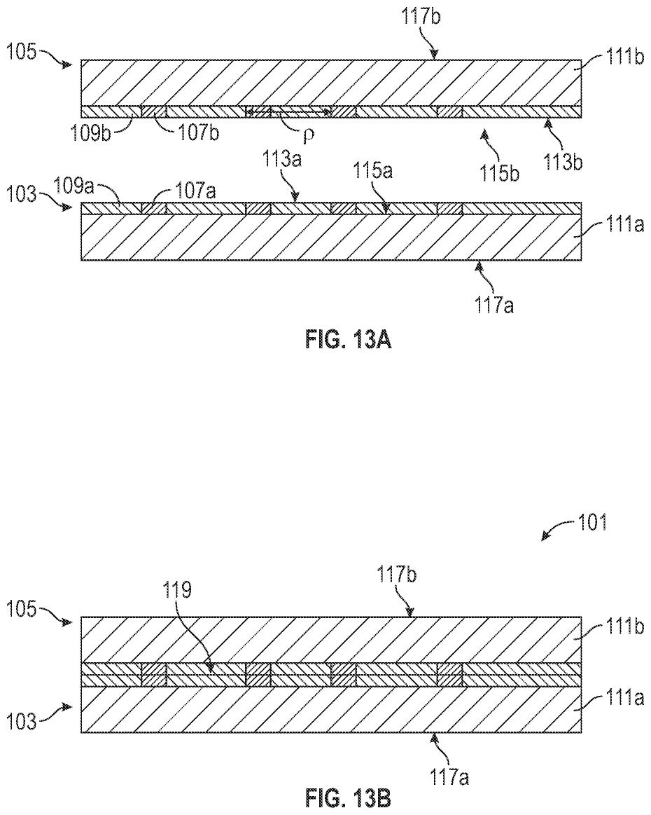

Various embodiments disclosed herein relate to directly bonded structures, such as integrated circuits 1201, in which two or more elements can be bonded directly to one another without an intervening adhesive. FIGS. 13A and 13B schematically illustrate a process for forming a directly hybrid bonded structure without an intervening adhesive according to some embodiments. In FIGS. 13A and 13B, a bonded structure 101 comprises two elements 103 and 105 that can be directly bonded to one another at a bond interface 119 (i.e., bonded directly to one another without an intervening adhesive. Two or more microelectronic elements 103 and 105 (such as semiconductor elements, including, for example, integrated device dies, wafers, passive devices, individual active devices such as power switches, etc.) may be stacked on or bonded to one another to form the bonded structure 101. Conductive features 107a (e.g., contact pads, exposed ends of vias (e.g., TSVs), or through-substrate electrodes) of a first element 103 may be electrically connected to corresponding conductive features 107b of a second element 105. Any suitable number of elements can be stacked in the bonded structure 101. For example, a third element (not shown) can be stacked on the second element 105, a fourth element (not shown) can be stacked on the third element, and so forth. Additionally or alternatively, one or more additional elements (not shown) can be stacked laterally adjacent one another along the first element 103. In some embodiments, the laterally stacked additional element may be smaller than the second element. In some embodiments, the laterally stacked additional element may be two times smaller than the second element.

In some embodiments, the elements 103 and 105 are directly bonded to one another without an adhesive. In various embodiments, a non-conductive field region that includes a non-conductive or dielectric material can serve as a first bonding layer 109a of the first element 103 which can be directly bonded to a corresponding non-conductive field region that includes a non-conductive or dielectric material serving as a second bonding layer 109b of the second element 105 without an adhesive. The non-conductive bonding layers 109a and 109b can be disposed on respective front sides 115a and 115b of device portions 111a and 111b, such as a semiconductor (e.g., silicon) portion of the elements 103, 103. Active devices and/or circuitry can be patterned and/or otherwise disposed in or on the device portions 111a and 111b. Active devices and/or circuitry can be disposed at or near the front sides 115a and 115b of the device portions 111a and 111b, and/or at or near opposite backsides 117a and 117b of the device portions 111a and 111b. Bonding layers can be provided on front sides and/or back sides of the elements. The non-conductive material can be referred to as a non-conductive bonding region or bonding layer 109a of the first element 103. In some embodiments, the non-conductive bonding layer 109a of the first element 103 can be directly bonded to the corresponding non-conductive bonding layer 109b of the second element 105 using dielectric-to-dielectric bonding techniques. For example, non-conductive or dielectric-to-dielectric bonds may be formed without an adhesive using the direct bonding techniques disclosed at least in U.S. Pat. Nos. 9,564,414; 9,391,143; and 10,434,749, the entire contents of each of which are incorporated by reference herein in their entirety and for all purposes. It should be appreciated that in various embodiments, the bonding layers 109a and/or 109b can comprise a non-conductive material such as a dielectric material, such as silicon oxide, or an undoped semiconductor material, such as undoped silicon. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials do not comprise polymer materials, such as epoxy, resin or molding materials.

In some embodiments, the device portions 111a and 111b can have a significantly different coefficients of thermal expansion (CTEs) defining a heterogenous structure. The CTE difference between the device portions 111a and 111b, and particularly between bulk semiconductor, typically single crystal portions of the device portions 111a, 111b, can be greater than 5 ppm or greater than 10 ppm. For example, the CTE difference between the device portions 111a and 111b can be in a range of 5 ppm to 101 ppm, 5 ppm to 40 ppm, 10 ppm to 101 ppm, or 10 ppm to 40 ppm. In some embodiments, one of the device portions 111a and 111b can comprise optoelectronic single crystal materials, including perovskite materials, that are useful for optical piezoelectric or pyroelectric applications, and the other of the device portions 111a, 111b comprises a more conventional substrate material. For example, one of the device portions 111a, 111b comprises lithium tantalate (LiTaO3) or lithium niobate (LiNbO3), and the other one of the device portions 111a, 111b comprises silicon (Si), quartz, fused silica glass, sapphire, or a glass. In other embodiments, one of the device portions 111a and 111b comprises a III-V single semiconductor material, such as gallium arsenide (GaAs) or gallium nitride (GaN), and the other one of the device portions 111a and 111b can comprise a non-III-V semiconductor material, such as silicon (Si), or can comprise other materials with similar CTE, such as quartz, fused silica glass, sapphire, or a glass.

In various embodiments, direct hybrid bonds can be formed without an intervening adhesive. For example, nonconductive bonding surfaces 113a and 113b can be polished to a high degree of smoothness. The nonconductive bonding surfaces 113a and 113b can be polished using, for example, chemical mechanical polishing (CMP). The roughness of the polished bonding surfaces 113a and 113b can be less than 30 Å rms. For example, the roughness of the bonding surfaces 113a and 113b can be in a range of about 0.1 Å rms to 15 Å rms, 0.5 Å rms to 10 Å rms, or 1 Å rms to 5 Å rms. The bonding surfaces 113a and 113b can be cleaned and exposed to a plasma and/or etchants to activate the surfaces 113a and 113b. In some embodiments, the surfaces 113a and 113b can be terminated with a species after activation or during activation (e.g., during the plasma and/or etch processes). Without being limited by theory, in some embodiments, the activation process can be performed to break chemical bonds at the bonding surfaces 113a and 113b, and the termination process can provide additional chemical species at the bonding surfaces 113a and 113b that improves the bonding energy during direct bonding. In some embodiments, the activation and termination are provided in the same step, e.g., a plasma to activate and terminate the surfaces 113a and 113b. In other embodiments, the bonding surfaces 113a and 113b can be terminated in a separate treatment to provide the additional species for direct bonding. In various embodiments, the terminating species can comprise nitrogen. For example, in some embodiments, the bonding surface(s) 113a, 113b can be exposed to a nitrogen-containing plasma. Further, in some embodiments, the bonding surfaces 113a and 113b can be exposed to fluorine. For example, there may be one or multiple fluorine peaks at or near a bond interface 119 between the first and second elements 103, 105. Thus, in the directly bonded structure 101, the bond interface 119 between two non-conductive materials (e.g., the bonding layers 109a and 109b) can comprise a very smooth interface with higher nitrogen content and/or fluorine peaks at the bond interface 119. Additional examples of activation and/or termination treatments may be found throughout U.S. Pat. Nos. 9,564,414; 9,391,143; and 10,434,749, the entire contents of each of which are incorporated by reference herein in their entirety and for all purposes. The roughness of the polished bonding surfaces 113a and 113b can be slightly rougher (e.g., about 1 Å rms to 30 Å rms, 3 Å rms to 20 Å rms, or possibly rougher) after an activation process.

In various embodiments, conductive features 107a of the first element 103 can also be directly bonded to corresponding conductive features 107b of the second element 105 without an adhesive (e.g., without solder or other conductive adhesive intervening between the conductive features 107a, 107b). For example, a direct hybrid bonding technique can be used to provide conductor-to-conductor direct bonds along the bond interface 119 that includes covalently direct bonded non-conductive-to-non-conductive (e.g., dielectric-to-dielectric) surfaces, prepared as described above. In various embodiments, the conductor-to-conductor (e.g., conductive feature 107a to conductive feature 107b) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes. In direct hybrid bonding embodiments described herein, conductive features are provided within non-conductive bonding layers, and both conductive and nonconductive features are prepared for direct hybrid bonding, such as by the planarization, activation and/or termination treatments described above. Thus, the bonding surface prepared for direct hybrid bonding includes both conductive and non-conductive features.

For example, non-conductive (e.g., dielectric) bonding surfaces 113a, 113b (for example, inorganic dielectric surfaces) can be prepared and directly bonded to one another without an intervening adhesive as explained above. Conductive contact features (e.g., conductive features 107a and 107b which may be at least partially surrounded by non-conductive dielectric field regions within the bonding layers 109a, 109b) may also directly bond to one another without an intervening adhesive. In various embodiments, the conductive features 107a, 107b can comprise discrete pads or traces at least partially embedded in the non-conductive field regions. In some embodiments, the conductive contact features can comprise exposed contact surfaces of through substrate vias (e.g., through silicon vias (TSVs)). In some embodiments, the respective conductive features 107a and 107b can be recessed below exterior (e.g., upper) surfaces (non-conductive bonding surfaces 113a and 113b) of the dielectric field region or non-conductive bonding layers 109a and 109b, for example, recessed by less than 30 nm, less than 20 nm, less than 15 nm, or less than 10 nm, for example, recessed in a range of 2 nm to 20 nm, or in a range of 4 nm to 10 nm. The recess can be at or near the middle or center of the cavity in which the conductive features 107a, 107b are disposed, and, additionally or alternatively, can extend or be disposed along sides of the cavity in which the conductive features 107a, 107b are disposed. In various embodiments, prior to direct bonding, the recesses in the opposing elements can be sized such that the total gap between opposing contact pads is less than 15 nm, or less than 10 nm. The non-conductive bonding layers 109a and 109b can be directly bonded to one another without an adhesive at room temperature in some embodiments and, subsequently, the bonded structure 101 can be annealed. Upon annealing, the conductive features 107a and 107b can expand and contact one another to form a metal-to-metal direct bond. Beneficially, the use of Direct Bond Interconnect, or DBI®, techniques commercially available from Adeia of San Jose, CA, can enable high density of conductive features 107a and 107b to be connected across the direct bond interface 119 (e.g., small or fine pitches for regular arrays). In some embodiments, the pitch of the conductive features 107a and 107b, such as conductive traces embedded in the bonding surface of one of the bonded elements, may be less than 101 microns or less than 10 microns or even less than 2 microns. For some applications, the ratio of the pitch of the conductive features 107a and 107b to one of the dimensions (e.g., a diameter) of the bonding pad is less than is less than 20, or less than 10, or less than 5, or less than 3 and sometimes desirably less than 2. In other applications, the width of the conductive traces embedded in the bonding surface of one of the bonded elements may range between 0.3 to 20 microns, e.g., in a range of 0.3 to 3 microns. In various embodiments, the conductive features 107a and 107b and/or traces can comprise copper, nickel, gold, indium, silver or their alloys, although other metals may be suitable. For example, the conductive features disclosed herein, such as the conductive features 107a and 107b, can comprise fine-grain metal (e.g., a fine-grain copper).

Thus, in direct bonding processes, a first element 103 can be directly bonded to a second element 105 without an intervening adhesive. In some arrangements, the first element 103 can comprise a singulated element, such as a singulated integrated device die. In other arrangements, the first element 103 can comprise a carrier or substrate (e.g., a wafer) that includes a plurality (e.g., tens, hundreds, or more) of device regions that, when singulated, form a plurality of integrated device dies. In some embodiments, the first element may comprise of a package or singulated package. Similarly, the second element 105 can comprise a singulated element, such as a singulated integrated device die. In other arrangements, the second element 105 can comprise a carrier or substrate (e.g., a wafer) or a package. The embodiments disclosed herein can accordingly apply to wafer-to-wafer (W2 W), die-to-die (D2D), or die-to-wafer (D2 W) package to wafer (P2 W), package to package, die to flat panel, package to flat panel bonding processes. In wafer-to-wafer (W2 W) processes, two or more wafers can be directly bonded to one another (e.g., direct hybrid bonded) and singulated using a suitable singulation process. After singulation, side edges of the singulated structure (e.g., the side edges of the two bonded elements) may be substantially flush and may include markings indicative of the common singulation process for the bonded structure (e.g., saw markings if a saw singulation process is used).

As explained herein, the first and second elements 103 and 105 can be directly bonded to one another without an adhesive, which is different from a deposition process and results in a structurally different interface compared to a deposition. In one application, a width of the first element 103 in the bonded structure is similar to a width of the second element 105. In some other embodiments, a width of the first element 103 in the bonded structure 101 is different from a width of the second element 105. Similarly, the width or area of the larger element in the bonded structure may be at least 10% larger than the width or area of the smaller element. The first and second elements 103 and 105 can accordingly comprise non-deposited elements. Further, directly bonded structures 101, unlike deposited layers, can include a defect region along the bond interface 119 in which nanometer-scale voids (nanovoids) are present. The nanovoids may be formed due to activation of the bonding surfaces 113a and 113b (e.g., exposure to a plasma). As explained above, the bond interface 119 can include concentration of materials from the activation and/or last chemical treatment processes. For example, in embodiments that utilize a nitrogen plasma for activation, a nitrogen peak can be formed at the bond interface 119. The nitrogen peak can be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH2 molecules, yielding a nitrogen-terminated surface. In embodiments that utilize an oxygen plasma for activation, an oxygen peak can be formed at the bond interface 119. In some embodiments, the bond interface 119 can comprise silicon oxynitride, silicon oxycarbonitride, or silicon carbonitride. As explained herein, the direct bond can comprise a covalent bond, which is stronger than van Der Waals bonds. The bonding layers 109a and 109b can also comprise polished surfaces that are planarized to a high degree of smoothness.

In various embodiments, the metal-to-metal bonds between the conductive features 107a and 107b can be joined such that metal grains grow into each other across the bond interface 119. In some embodiments, the metal is or includes copper, which can have grains oriented along the 111 crystal plane for improved copper diffusion across the bond interface 119. In some embodiments, the conductive features 107a and 107b may include nanotwinned copper grain structure, which can aid in merging the conductive features during anneal. The bond interface 119 can extend substantially entirely to at least a portion of the bonded conductive features 107a and 107b, such that there is substantially no gap between the non-conductive bonding layers 109a and 109b at or near the bonded conductive features 107a and 107b. In some embodiments, a barrier layer may be provided under and/or laterally surrounding the conductive features 107a and 107b (e.g., which may include copper). In other embodiments, however, there may be no barrier layer under the conductive features 107a and 107b, for example, as described in U.S. Pat. No. 11,195,748, which is incorporated by reference herein in its entirety and for all purposes.

Beneficially, the use of the hybrid bonding techniques described herein can enable extremely fine pitch between adjacent conductive features 107a and 107b, and/or small pad sizes. For example, in various embodiments, the pitch p (i.e., the distance from edge-to-edge or center-to-center, as shown in FIG. 13A) between adjacent conductive features 107a (or 107b) can be in a range of 0.5 microns to 50 microns, in a range of 0.75 microns to 25 microns, in a range of 1 micron to 25 microns, in a range of 1 micron to 10 microns, or in a range of 1 micron to 5 microns. Further, a major lateral dimension (e.g., a pad diameter) can be small as well, e.g., in a range of 0.25 microns to 30 microns, in a range of 0.25 microns to 5 microns, or in a range of 0.5 microns to 5 microns.

As described above, the non-conductive bonding layers 109a, 109b can be directly bonded to one another without an adhesive and, subsequently, the bonded structure 101 can be annealed. Upon annealing, the conductive features 107a, 107b can expand and contact one another to form a metal-to-metal direct bond. In some embodiments, the materials of the conductive features 107a, 107b can interdiffuse during the annealing process.

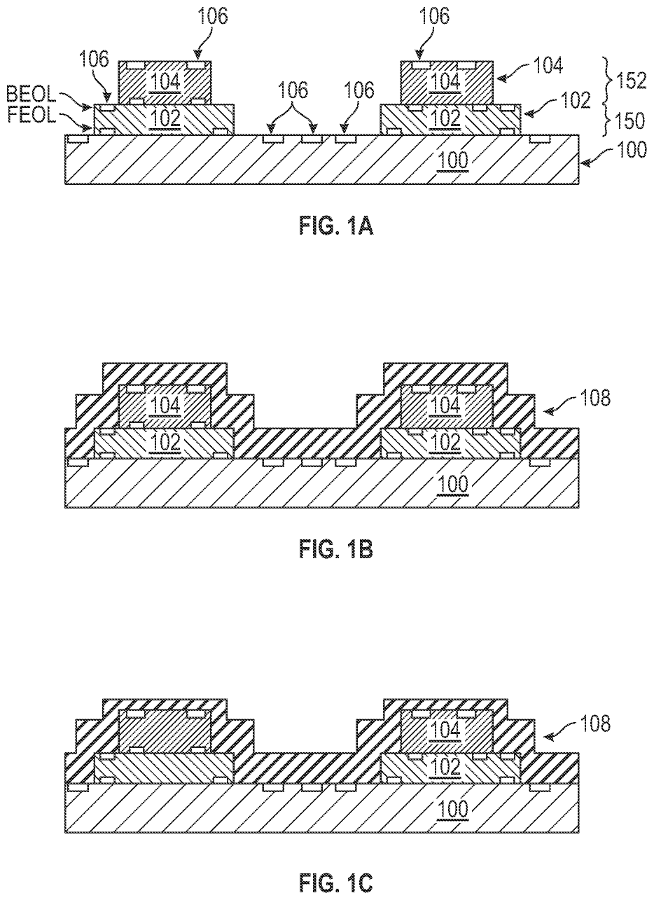

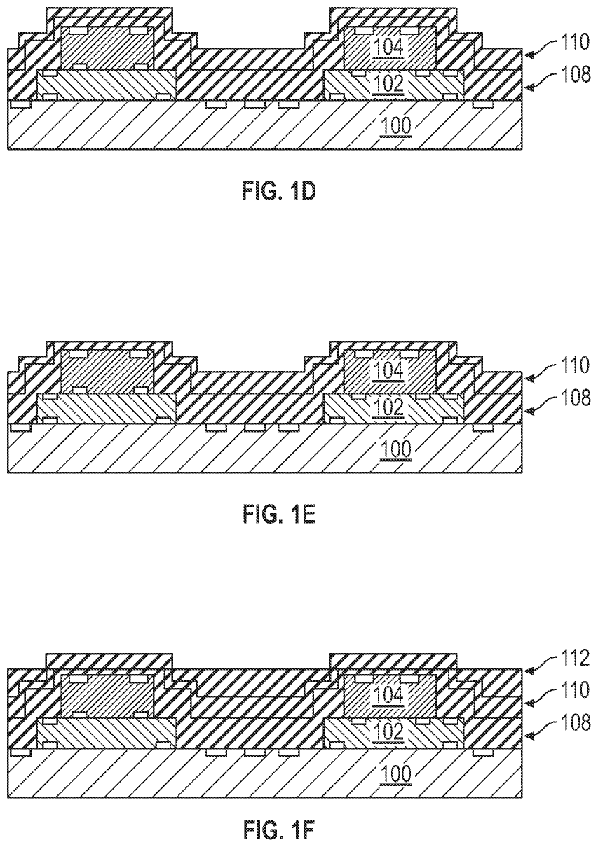

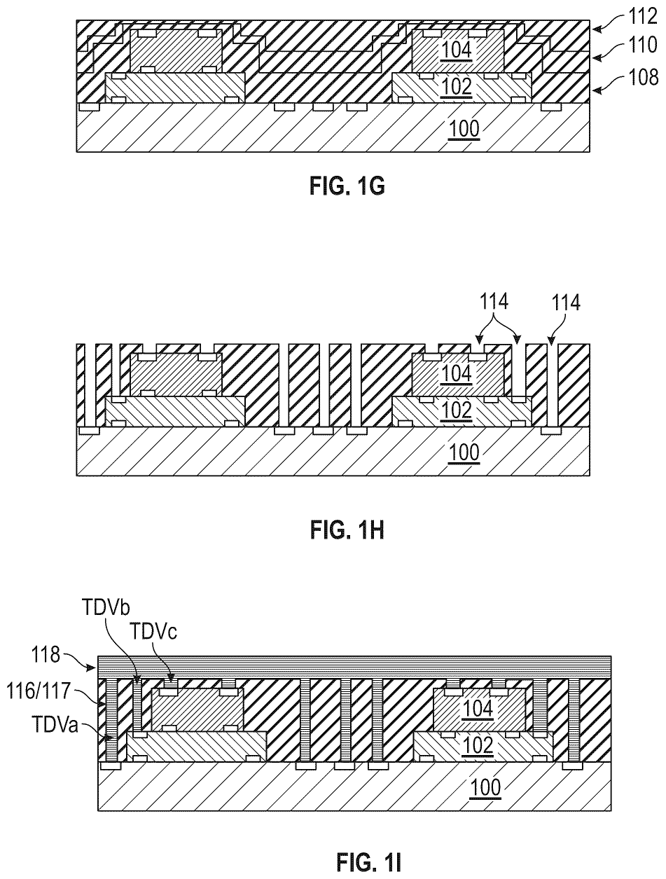

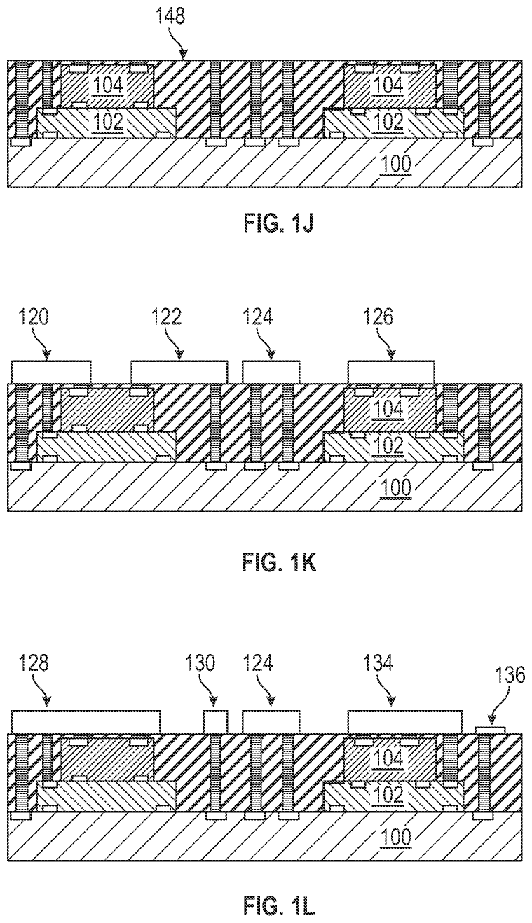

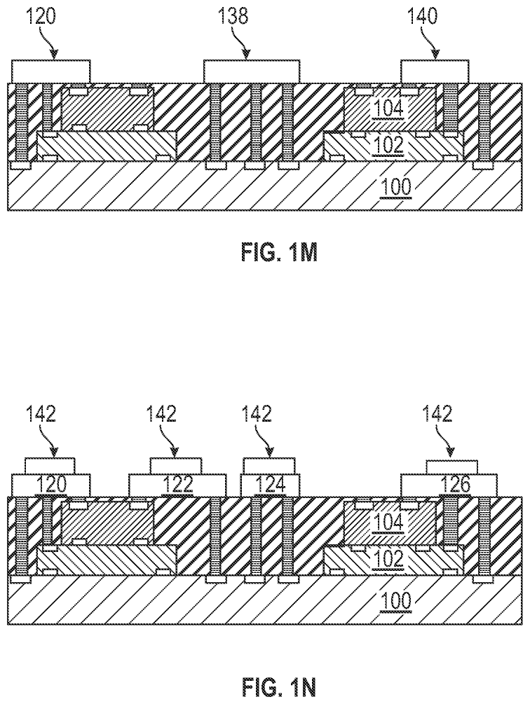

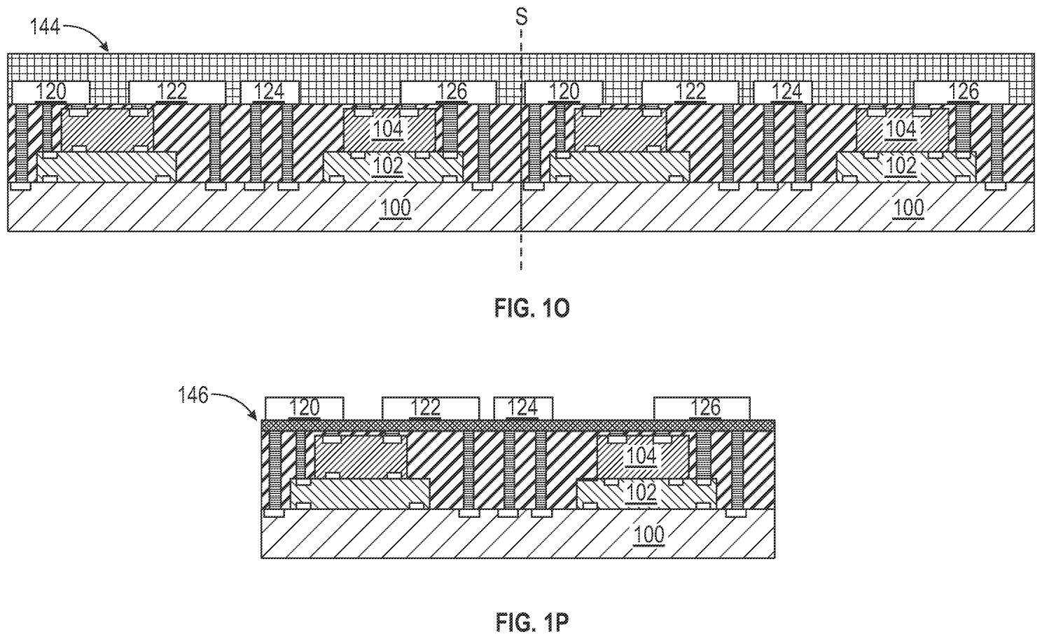

FIGS. 1A-1P schematically illustrate cross-sectional views of a method of making example topographic packages according to some embodiments of the disclosed technology. Referring to FIG. 1A, a substrate 100 or carrier may be provided. The substrate 100 may be made of any suitable material, such as but not limited to silicon (Si), III-V semiconductors such as gallium arsenide (GaAs), II-VI semiconductors such as cadmium selenide CdSe and CdTe cadmium telluride, ceramics, carbon-based substrates such as diamond, silicon carbon (SiC), germanium (Ge), Si1−xGex, or the like. Even though a semiconductor substrate 100 as provided from an in-process wafer is generally described below, any sheet or layer semiconductor material or dielectric material, such as ceramic or glass for example, may be used as a substrate. In some arrangements, the substrate 100 may comprise of a package, with or without partial or full embedded dies or passive elements. As illustrated in FIG. 1A, the substate may include conductive contact features, or contact pads 106, which allow electrical contact with a front or top surface of the substrate 100. The back or bottom surface can comprise conductive lands or terminals configured to connect to another device, such as a system board or another electronic assembly by way of any suitable electrical connection (e.g., by solder balls, by direct hybrid bonding, etc.).

Also illustrated in FIG. 1A, one or more first dies 102 may be located in a first device level 150 and one or more second dies 104 located in a second device level 152 located above the first device level. In an embodiment, the second die 104 can be smaller than the first die 102; e.g., the upper second die 104 can have a smaller lateral footprint than the lower first die 102. Further, as illustrated in FIG. 1A, the first and second dies 102, 104 may have contact pads 106 located on the front side, the back side, or both the front and back sides of the first and second dies 102, 104. In a preferred embodiment, the first dies 102 are attached to the substate 100 with hybrid bonding and the second dies 104 are attached to the first dies 102 with hybrid bonding.

Referring to FIG. 1B, a first dielectric layer 108 may be deposited over the substrate 100, the first dies 102 and the second dies 104. The first dielectric layer 108 may be an inorganic dielectric, such as silicon oxide (SiO₂), silicon nitride (Si₃N₄), silicon oxynitride (SiOₓN_{y}), or any other suitable dielectric material. As shown in FIG. 1B, the first dielectric layer 108 can be conformally coated over the first and second die levels, e.g., over the first and second dies 102, 104 of each die stack.

Referring to FIG. 1C, an upper surface of the first dielectric layer 108 is planarized. Any suitable method of planarizing may be used, such as chemical mechanical polishing (CMP).

Referring to FIG. 1D, a second dielectric layer 110 may be deposited over the first dielectric layer 108. The second dielectric layer 110 may be made of the same dielectric material as the first dielectric layer 108 or a different dielectric material.

Referring to FIG. 1E, an upper surface of the second dielectric layer 108 is planarized. Any suitable method of planarizing may be used, such as CMP.

Referring to FIG. 1F, a third dielectric layer 112 may be deposited over the second dielectric layer 110. The third dielectric layer 112 may be made of the same dielectric material as the first and second dielectric layers 108, 110 or a different dielectric material.

Referring to FIG. 1G, an upper surface of the third dielectric layer 112 is planarized. Any suitable method of planarizing may be used, such as CMP. As illustrated in the Above figures, three dielectric layers 112 have been deposited. However, any number of dielectric layers may be deposited, such as 4, 5, 6 or more layers.

Referring to FIG. 1H, via holes 114 are formed through the first, second and third dielectric layers 108, 110, 112 such that some of the via holes 114 contact the substrate 100, some of the via holes 114 contact the first dies 102 and some of the via holes 114 contact the second dies 104. The via holes 114 may land on any portion of second dies 104. In some embodiments, the contact pads 106 maybe arrayed around a peripheral portion of the second dies 104 or alternatively across essentially the entire surface of the second dies 104, for example in a ball grid array pattern. As illustrated, dies 104 have a smaller footprint than first dies 102. As such, the contact pads 106 are generally array around the periphery of the first dies 102. Note, however, the second dies 104 may have additional bond pads in an interior portion of the surface, allowing direct communication between the first dies 102 and the second dies 104. The via holes 114 may be formed by any suitable method such as reactive ion etching (RIE) or chemical wet etching.

Referring to FIG. 1I, a barrier layer/adhesion layer 116/117 is deposited such that the barrier layer/adhesion layer 116/117 conformally coats the surfaces of the via holes 114. A metallization layer 118 is then deposited over the barrier layer/adhesion layer 116/117 forming through dielectric vias TDVa, TDVb, TDVc extending to the substrate 100 and the first and second dies 102, 104. Any suitable method may be used to conformally deposit the barrier layer/adhesion layer 116/117, such as atomic layer deposition (ALD) and chemical vapor deposition (CVD). In an embodiment, the barrier layer/adhesion layer 116/117 comprises a separate barrier layer 116 and adhesion layer 117. Suitable materials for the barrier layer 116, include but are not limited to cobalt, ruthenium, tantalum, tantalum nitride, indium oxide, tungsten nitride, and titanium nitride. The adhesion layer 117 may be a seed layer made of the same material as the metallization layer 118 or the adhesion layer 117 may be a dielectric layer such as SiNx or SiOx. The metallization layer 118 may be made of any conductive material such as copper, nickel, gold, silver, indium, tantalum, tungsten, alloys thereof and silicides thereof.

Referring to FIG. 1J, CMP is performed to remove excess metallization layer 118 material and excess barrier layer/adhesion layer 116/117 material. The CMP also planarizes the surface of the third dielectric layer 112, thereby forming a bonding surface 148 suitable for hybrid bonding.

Referring to FIGS. 1K-1M, third dies 120, 122, 124, 126, 128, 130, 134, 138 may be direct hybrid bonded to the topographic package in various configurations. Third dies 120, 122, 124, 126, 128, 130, 134, 138 may be located in a third device level, distinct from the first and second device levels. For example, third die 120 includes electrical connections TDVa, TDVb, TDVc to the substrate 100, a first die 102 in the first device level and a second die 104 in the second device level. Third die 122 includes electrical connections to the substrate 100 and a second die 104 in the second device level. In some embodiments, the third die 124 only has electrical connections to the substrate 100, such that the TDVs connected to the third die 124 bypass the first and second dies 102, 104. Further, in the illustrated embodiment, the third die 126 only has electrical connections to a second die 104. In an embodiment, the third die 126 is hybrid bonded directly to the second die 104. That is, a through dielectric via TDVc may not be utilized. In FIG. 1L, third die 128 includes electrical connections to the substrate 100, the first die 102 in the first device level and the second die 104 in the second device level. As shown, the third die 128 can have a footprint larger than the underlying second die 104.

Third die 130 is a chiplet mounted to (e.g., directly bonded to) the dielectric layer 112 and electrically connected to the substrate 100 by way of TDVs TDVa. Chiplets are small integrated circuit dies with specialized functionality. Chiplets may be one part of a processing module that makes up a larger integrated circuit like a computer processor. Rather than manufacturing a processor on a single piece of silicon with the desired number of cores, chiplets allow manufacturers to use multiple smaller chips to make up a larger integrated circuit. Third die 134 is electrically connected to a first die 102 and a second die 104. In some embodiments, an upper bond pad 136 can be provided on the upper surface of the dielectric layer 112, which allows an electrical connection (e.g., power, ground, signal, etc.) to be provided to the topographic package via an electrical connector such as a wire bond, ribbon interconnect, etc. In some embodiments, the bond pad 136 can serve as a test pad to test the functionality of one or more of the illustrated dies.

Referring to FIG. 1N, one or more fourth dies 142 may be hybrid bonded to the third dies 120, 122, 124, 126, 128, 134 in a fourth device level distinct from the first, second and third device levels.

Referring to FIG. 1O, a protective layer 144 may be deposited over the topographic package. In an embodiment, multiple topographic packages are simultaneously fabricated on a single wafer. In this embodiment, the protective layer 144 helps to protect the topographic packages when they are singulated into individual topographic packages. FIG. 1O illustrates a reconstituted wafer with two finished cells. Streets S may be formed between the finished cells along which the cells may be singulated. Singulation may be performed in any suitable manner, such as by sawing, laser cutting, etching, plasma cutting, or any combinations thereof etc. In various embodiments, the protective layer 144 can comprise an organic protective layer, such as a photoresist material.

Referring to FIG. 1P, an embodiment of a topographic package that includes a redistribution layer (RDL) 146 between the top surface of the third dielectric layer 112 and the third dies 120, 122, 124, 126, 128, 130, 134. An RDL may include one or a plurality of dielectric layers (e.g., inorganic dielectric layers such as silicon oxide, silicon nitride, etc.), and conductive traces and pads at least partially embedded in the dielectric layers. The RDL 146 can convey signals (or power and ground) laterally through the traces so as to connect dies laterally spaced apart from one another. When an integrated circuit is manufactured, it usually has a set of I/O pads that are wirebonded to the pins of the package. The redistribution layer is an extra layer of wiring on the chip that enables bond out from different locations on the chip, making chip-to-chip bonding simpler. The RDL may also be used for spreading the contact points around the die so that thermal stress can be spread.

Conventional methods of forming topographic packages are expensive. These methods require many dielectric layer depositions and subsequent intermediate planarization steps. The conventional methods also require long times for deep dielectric cavity etching and long times for deep cavity filling. The present embodiment can be performed with relatively few dielectric deposition steps and consequently with relatively few intermediate planarization steps. Further, the present embodiment provides vias which connect to the substrate 100, the first dies 102 and the second dies 104 which may result in improved communication between the dies 102, 104 and improve performance. In addition, the use of direct hybrid bonding allows for better integration and finer pitches.

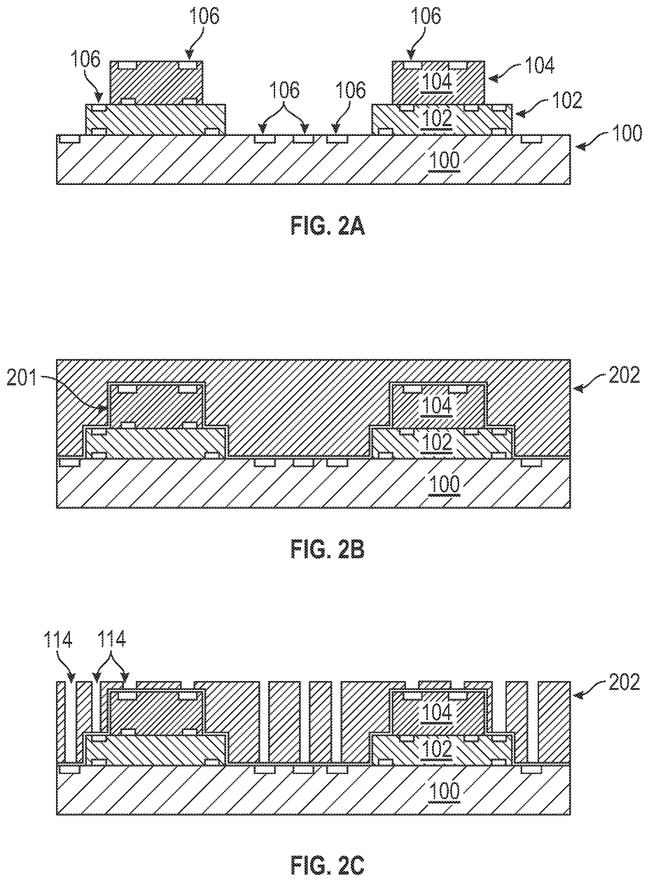

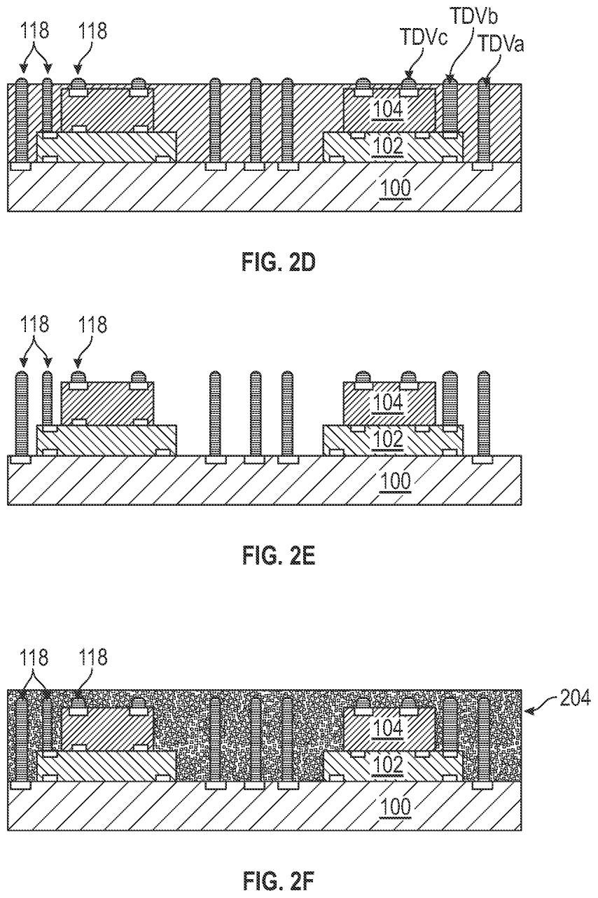

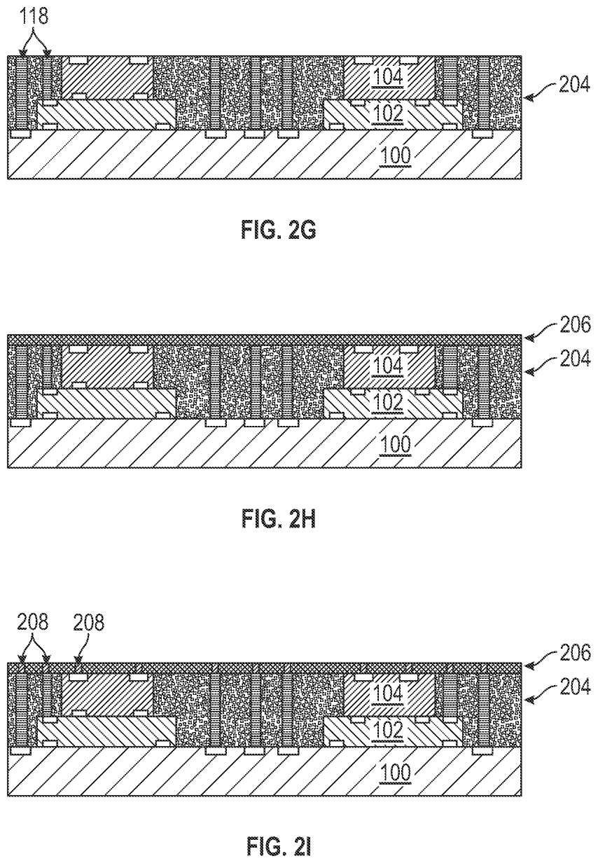

FIGS. 2A-2J schematically illustrate cross-sectional views of another method of making example topographic packages according to some embodiments of the disclosed technology. This method may be referred to as a though-mask plating method. Referring to FIG. 2A, similarly to the first embodiment, a substrate 100 may be provided. As illustrated in FIG. 2A, the substate may include contact pads 106 which allow electrical contact with the substrate 100. Also illustrated in FIG. 2A, one or more first dies 102 may be located in a first device level and one or more second dies 104 may be located in a second device level located above the first device level. In an embodiment, the second die 104 is smaller than the first die 102. Further, as illustrated in FIG. 2A, the first and second dies 102, 104 may have contact pads 106 located on a first side of the first and second dies 102, 104. In a preferred embodiment, the first dies 102 are attached to the substate 100 by a hybrid bonding technique and the second dies 104 are attached to the first dies 102 by a hybrid bonding technique.

Referring to FIG. 2B, a seed layer 201 may be deposited over the substrate 100. The seed layer 201 may made of the same material as the metallization layer 118 discussed below. Then, a photoresist layer 202 may be deposited over the seed layer 201.

Referring to FIG. 2C, the photoresist layer 202 may then be patterned to form via holes 114 extending to the contact pads 106 on the substrate 100, the first dies 102 and the second dies 104. The photoresist may be either negative photoresist, in which the portion of the photoresist that is exposed to light becomes insoluble to the photoresist developer or a positive photoresist, in which the portion of the photoresist that is exposed to light becomes soluble to the photoresist developer. The patterned photoresist layer 202 forms the through-mask giving rise to the name of this embodiment method.

Referring to FIG. 2D, electrically conductive material is deposited in the via holes 114 to form vias 118. The vias may be formed by ALD, CVD or any other suitable method.

Referring to FIG. 2E, the photoresist layer 202 may be removed. Removal of the photoresist layer 202 may be performed by wet chemical etching processes or by ashing. Additionally, the remaining seed layer 201 is also removed.

Referring to FIG. 2F, a low CTE dielectric layer 204 may be deposited over the substrate 100, the first dies, 102 and the second dies 104. In some embodiments, the low CTE material has a CTE of less than or equal to 14 ppm/° C. at room temperature. In other embodiments, the CTE is less than or equal to 10 ppm/° C. By comparison, high CTE materials can have a CTE of greater than 15 ppm/° C., such as between 15 and 30 ppm/° C. In some embodiments, the first low stress dielectric layer 501 may comprise more than one dielectric layer. For example, a layer of material having a CTE of 12 to 20 ppm/C may be coated with a material having a CTE of less than 12 ppm/° C. to improve the toughness of the structure. In an embodiment, the low CTE dielectric layer 204 may comprise particles embedded in a polymer. For example, the low CTE dielectric layer 204 may comprise SiO₂ particles embedded in a resin or polyimide matrix. In some embodiments, the particles resin may comprise aluminum nitride (AlN) or carbon to improve heat transfer and provide better thermal conductivity. Other particle and matrix materials may be used as well.

Referring to FIG. 2G, the top surface of the low CTE dielectric layer 204 may be planarized. Planarization may be accomplished with CMP.

Referring to FIG. 2H, a bonding dielectric layer 206 may be deposited over the planarized low CTE dielectric layer 204. The bonding dielectric layer 206 may comprise an inorganic dielectric, such as silicon oxide SiO₂, silicon nitride Si3N4, silicon oxynitride SiOxNy, or any other suitable dielectric material.

Referring to FIG. 2I, conductive contact features 208 may be formed in the bonding dielectric layer 206. The conductive features 208 may comprise the same material as the vias 118 or be made of a different conductive material. The conductive features provide electrical contact between third layer dies (described below) and the substrate 100, the first dies 102 and the second dies 104. In various embodiments, cavities can be formed in the dielectric layer 206, and the conductive features 208 can be deposited in the cavities. In some embodiments, the dielectric layer 206 and the conductive features 208 can be planarized and prepared for direct hybrid bonding as described herein. In other embodiments, the conductive features may comprise wire bond pads, and bonding wires (not shown) can electrically connect the conductive features 208 to other devices or dies.

Referring to FIG. 2J, any of third dies 120, 122, 124, 126, 128, 130, 134, 138 as discussed in regard to the first embodiment can be hybrid bonded to the bonding dielectric layer 206 and the conductive features 208. Further, as in the first embodiment, one or more fourth dies 142 may be hybrid bonded to the third dies 120, 122, 124, 126, 128, 134 in a fourth device level. The present embodiment provides many of the benefits of the previous embodiment but provides the further benefit of not requiring multiple dielectric depositions and multiple intermediate planarization steps. The use of a single photoresist through-mask simplifies the process, reduces steps and thereby lowers costs.

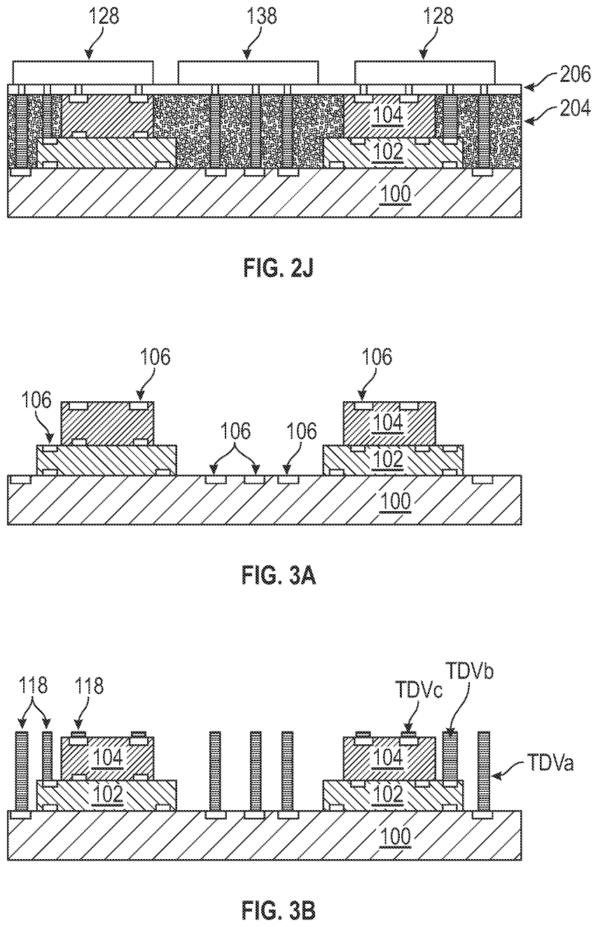

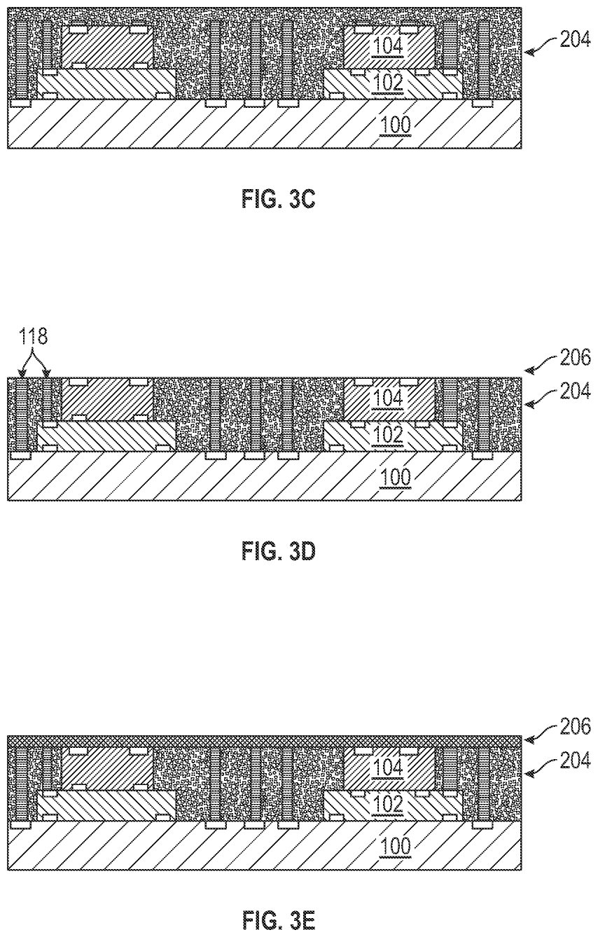

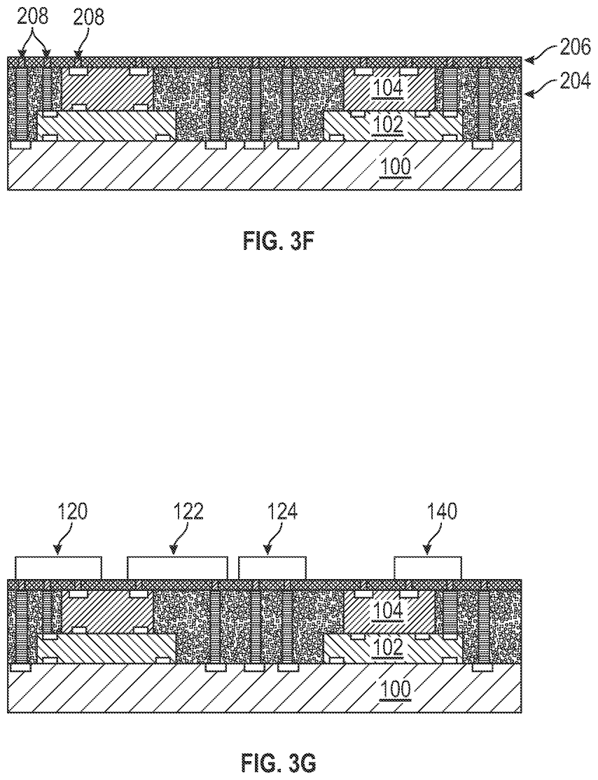

FIGS. 3A-3G schematically illustrate cross-sectional views of another method of making example topographic packages according to some embodiments of the disclosed technology. In regards to FIG. 3A, similar to the embodiments discussed above, a substrate 100 may be provided having first and second dies 102, 104 hybrid bonded thereon. Further, the substrate 100, the first dies 102 and the second dies 104 may have contact pads 106 located on the front side, the back side, or both the front and back sides of the first and second dies 102, 104.

Referring FIG. 3B, vias 118 may be printed on the contact pads 106. The vias 118 may be printed by 3D printing or any other suitable printing method, such as screen printing. The vias 118 may be made of copper, silver, nickel, or alloys thereof. In an embodiment, the vias 118 comprise nanoparticles. The nanoparticles may have a size in the range of about 1 nm to 1000 nm, such as 10 nm to 500 nm, such 50 nm to 250 nm. In various embodiments, half the nanoparticles have a size less than 100 nm. By printing vias 118 directly on the contact pads 106, the deposition of multiple dielectric layers and multiple planarization steps can be eliminated. Further, there is no need to form a through-mask as in the previous method.

Referring to FIG. 3C, the in-process package illustrated in FIG. 3B may be heated to sinter the nanoparticles. That is, heated to a sufficient temperature for a sufficient amount of time to cause the particles to coalesce into a solid mass without liquifying the particles. In this manner, the vias 118 gain structural integrity and improved electrical conductivity. After heating, low CTE dielectric layer 204 may be deposited over the substrate 100, the first dies 102, the second dies 104 and the conductive features 118. In an alternative method, the low CTE dielectric layer 204 may be deposited prior to sintering the nanoparticles. As discussed above in regards to the second embodiment, the low CTE dielectric layer 204 may comprise SiO₂ particles embedded in a resin or polyimide matrix.

Referring to FIG. 3D, the top surface of the low CTE dielectric layer 204 may be planarized. Planarization may be accomplished, for example, with CMP.

Referring to FIG. 3E, a bonding dielectric layer 206 may be deposited over the planarized low CTE dielectric layer 204. The bonding dielectric layer 206 may comprise an inorganic dielectric, such as silicon oxide SiO₂, silicon nitride Si3N4, silicon oxynitride SiOxNy, or any other suitable dielectric material.

Referring to FIG. 3F, conductive features 208 may be formed in the bonding dielectric layer 206. The conductive features 208 may comprise the same material as the vias 118 or be made of a different conductive material. The conductive features allow electrical contact with the substrate 100, the first dies 102 and the second dies 104.

Referring to FIG. 3G, any of third dies 120, 122, 124, 126, 128, 130, 134, 138 as discussed in regard to the first embodiment can be hybrid bonded to the bonding dielectric layer 206 and the conductive features 208. Further, as in the first embodiment, one or more fourth dies 142 may be hybrid bonded to the third dies 120, 122, 124, 126, 128, 134 in a fourth device level.

As discussed above, the present embodiment is advantageous because by printing vias 118 directly on the contact pads 106, the deposition of multiple dielectric layers and multiple planarization steps can be eliminated. Further, there is no need to form a through-mask as in the previous method.

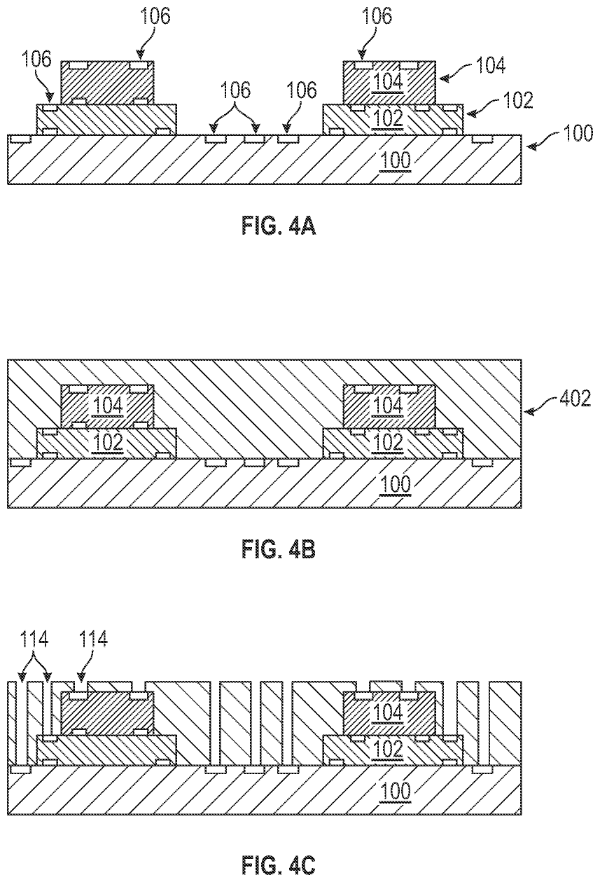

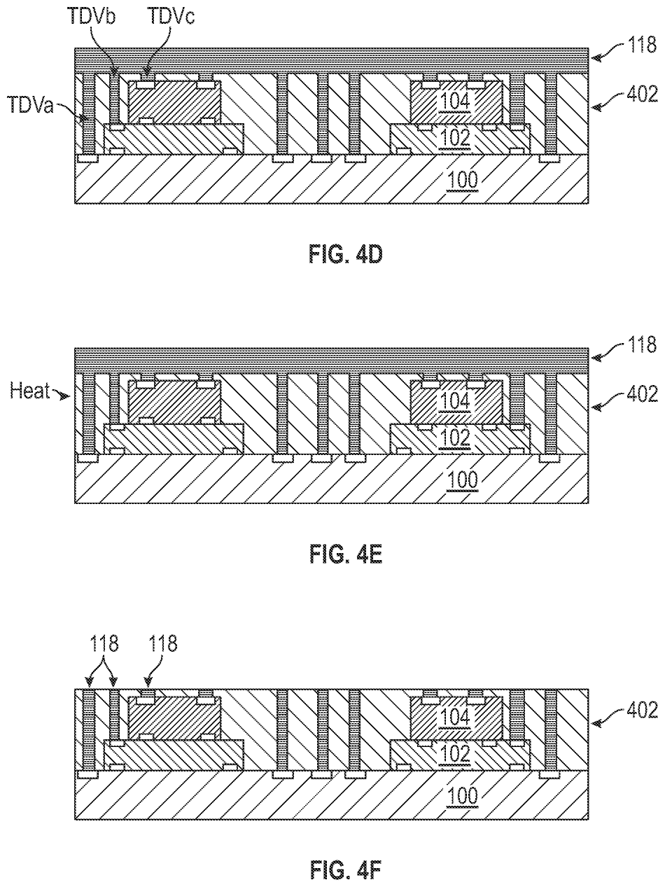

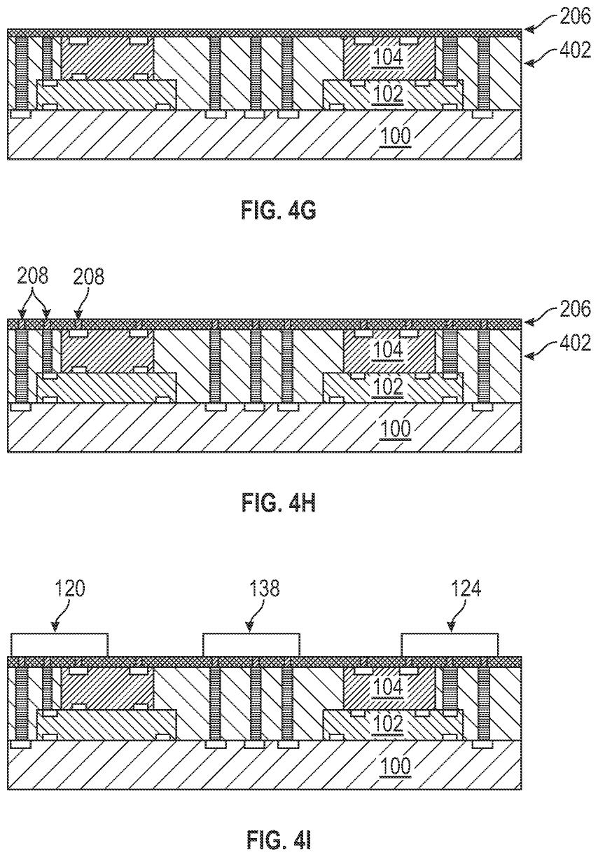

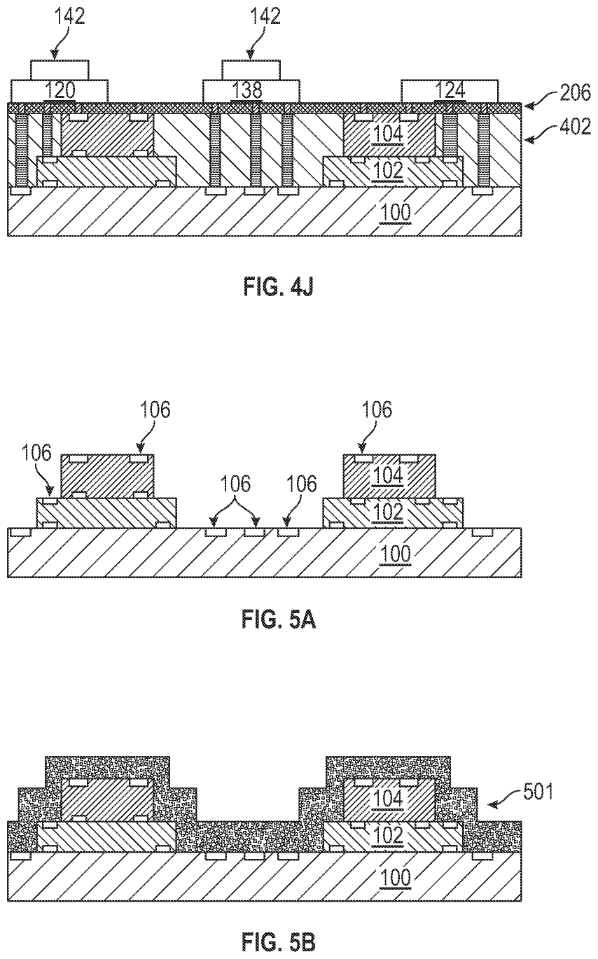

FIGS. 4A-4J schematically illustrate cross-sectional views of a method of making example topographic packages according to some embodiments of the disclosed technology. In regards, the FIG. 4A, similar to the embodiments discussed above, a substrate 100 may be provided having first and second dies 102, 104 hybrid bonded thereon. Further, the substrate 100, the first dies 102 and the second dies 104 may have contact pads 106 formed thereon. As in previous embodiments, the contact pads 106 may be located on the front side, the back side, or both the front and back sides of the first and second dies 102, 104.

Referring to FIG. 4B, an organic layer 402 may be deposited over the substrate 100, the first dies 102 and the second dies 104. The organic layer 402 may comprises a dielectric material such as a resin, polyimide or any other suitable organic dielectric material. In some arrangements, the resin may comprise of particulate materials. In some embodiments, the organic material may comprise of a liquid crystal polymer. The organic layer may be spin coated or laminated or formed by other known methods. In some embodiments, the CTE of the organic layer 402 is less than 20 ppm/° C. or less than 10 ppm/° C.

Referring to FIG. 4C, via holes 114 may be formed in the organic layer 402. In an embodiment, a photolithographic mask (not shown) may be formed over the organic layer 402 and the via holes 114 formed via chemical wet etching or dry etching, such as with reactive ion etching or laser ablation. After forming the via holes 114, the photolithographic mask may be removed.

Referring to FIG. 4D, a metallization layer may be formed in the via holes 114 and over the organic layer 412. As in previous embodiments, barrier/adhesion layers 116/117 may be deposited prior to depositing the metallization layer 118. In an embodiment, the metallization layer 118 may comprise metal nanoparticles, for example copper or nickel or silver or their respective alloys. The formed metallization layer may be annealed at a higher temperature before the planarization step. In an embodiment, 3D printing or any other suitable printing method may be used to fill the via holes 114.

Referring to FIG. 4E, the in-process topographic package may then be heated to sinter the nanoparticles.

Referring to FIG. 4F, the top surface of the in-process topographic package may be planarized to removed excess metallization material and barrier/adhesion material.

Referring to FIG. 4G, a bonding dielectric layer 206 may be deposited over the planarized top surface of the in-process topographic package. The bonding dielectric layer 206 may be silicon oxide SiO₂, silicon nitride Si₃N₄, silicon oxynitride SiOₓN_{y}, or any other suitable dielectric material.

Referring to FIG. 4H, conductive features 208 may be formed in the bonding dielectric layer 206. The conductive features 208 may comprise the same material as the vias 118 or be made of a different conductive material. The conductive features allow electrical contact with the substrate 100, the first dies 102 and the second dies 104.

Referring to FIGS. 4I and 4J, any of third dies 120, 122, 124, 126, 128, 130, 134, 138 as discussed in regard to the first embodiment can be hybrid bonded to the bonding dielectric layer 206 and the conductive features 208. Further, as in the first embodiment, one or more fourth dies 142 may be hybrid bonded to the third dies 120, 122, 124, 126, 128, 134 in a fourth device level.

The present embodiment includes a through-mask similar to the embodiment illustrated in FIGS. 2A-2J above. However, instead of depositing the metallization layer 118 using ALD, CVD the metallization layer 118 may be printed such as by 3D printing, screen printing or any other suitable printing method.

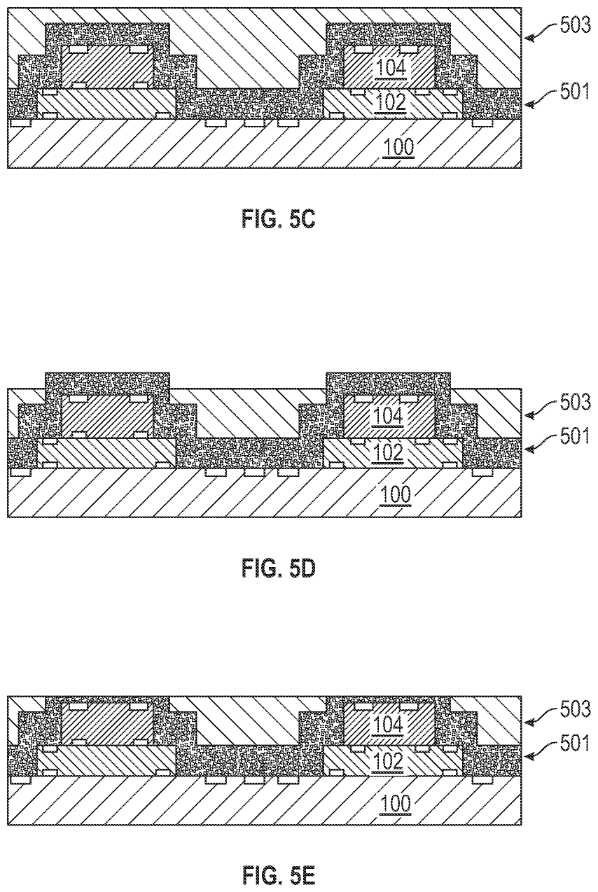

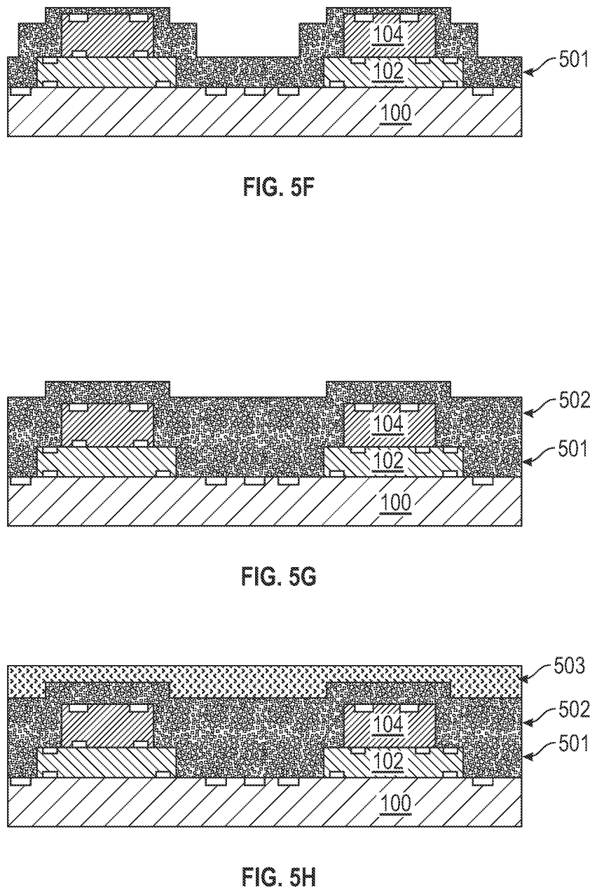

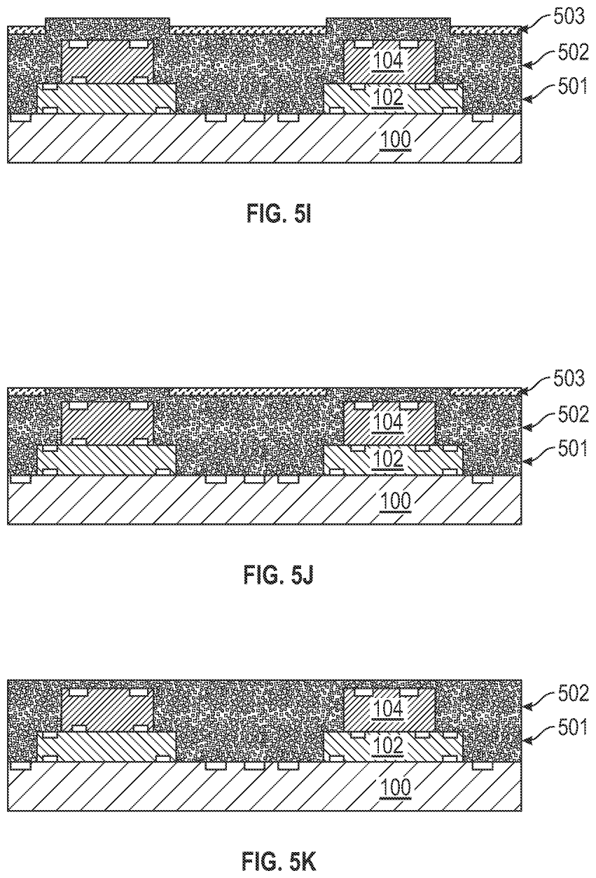

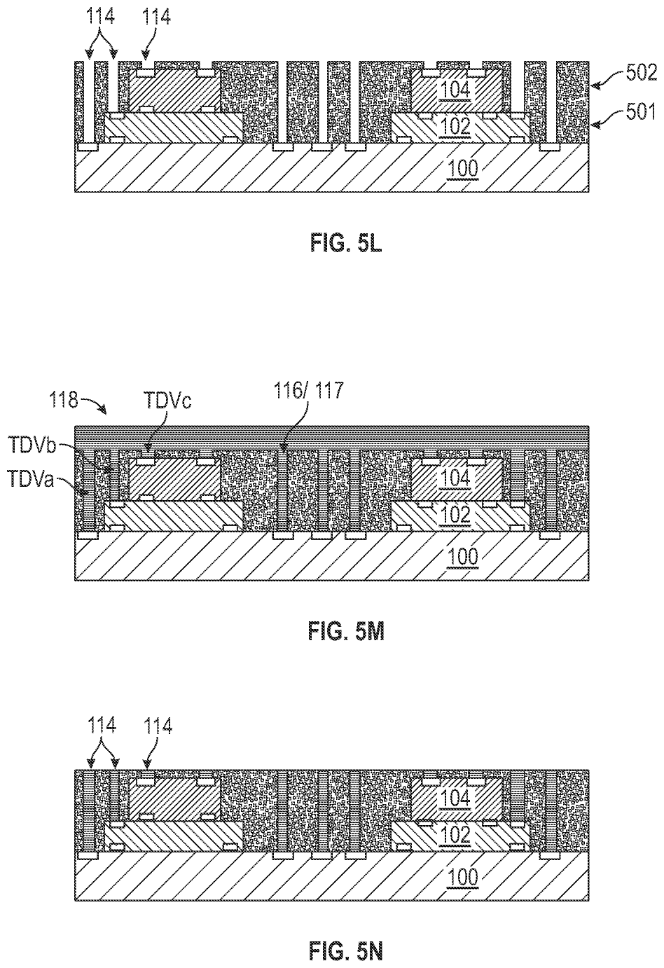

FIGS. 5A-5O schematically illustrate cross-sectional views of a method of making example topographic packages according to some embodiments of the disclosed technology. This embodiment method may be referred to as the selective dielectric wet etch method. In regards to FIG. 5A, similar to the embodiments discussed above, a substrate 100 may be provided having first and second dies 102, 104 hybrid bonded thereon. Further, the substrate 100, the first dies 102 and the second dies 104 may have contact pads 106 formed thereon. As in the above embodiments, the contact pads 106 may be located on the front side, the back side, or both the front and back sides of the first and second dies 102, 104.

Referring to FIG. 5B, a low CTE dielectric layer 204 may be deposited over the substrate 100, the first dies 102 and the second dies 104. As discussed above, the low CTE dielectric layer 204 may comprise particles embedded in a polymer. For example, the low CTE dielectric layer 204 may comprise SiO₂ particles embedded in a resin or polyimide matrix. Other particle and matrix materials may be used as well.

Referring to FIG. 5B, a first low stress dielectric layer 501 may be deposited over the substrate 100, the first dies 102 and the second dies 104. Typically, stress for PECVD SiO₂ is about 350 MPa and may be as high as 800 MPa in compression. In some embodiments, the first low stress dielectric layer 501 has a stress less than 200 MPa. In other embodiments, the first low stress dielectric layer 501 has a stress less than 100 MPa. In other embodiments, the first low stress dielectric layer 501 has a stress less than 40 MPa (which can be in compression). In some embodiments, the first low stress dielectric layer 501 has a stress in a range of −20 to 100 MPa. In some embodiments, the tensile modulus of the first dielectric layer 501 may be in the range of 1 GPa to 70 GPa. In other embodiments, the tensile modulus of the first dielectric layer 501 may be in the range of 4 GPa to 50 GPa. In other embodiments, the tensile modulus of the first dielectric layer 501 may be in the range of 14 GPa to 40 GPa. The first low stress dielectric layer 501 may be a silicon oxide SiO₂, silicon nitride Si₃N₄, silicon oxynitride SiOₓN_{y}, or any other suitable dielectric material. The first low stress dielectric layer 501 preferably has a thickness in the range of 10-50 microns to reduce stress.

Referring to FIG. 5C, a planarizing layer 503 may be deposited over the first low stress dielectric layer 501. In this embodiment, the planarizing layer 503 may comprises an insulating material, e.g., a polymer material, such as a photoresist, resin or polyimide.

Referring to FIG. 5D, a portion of the planarizing layer 503 is removed, exposing a portion of the first low stress dielectric layer 501. In particular, the level of the planarizing layer 503 is lowered below the top surface of the first low stress dielectric layer 501 over the first and second dies 102, 104. Removal may be accomplished by, for example, by ashing, e.g., exposing the planarizing layer 503 to an oxygen plasma.

Referring to FIG. 5E, the in-process topographic package is planarized to thin a top portion of the exposed first low stress dielectric layer 501. Planarization may accomplished with CMP.

Referring to FIG. 5F, the planarizing layer 503 is removed. Removal may be accomplished by wet chemical etching or ashing or other know methods.

Referring to FIG. 5G, a second low stress dielectric layer 502 may be deposited over the first low stress dielectric layer 501. The second low stress dielectric layer 502 may be a silicon oxide SiO₂, silicon nitride Si₃N₄, silicon oxynitride SiOₓN_{y}, or any other suitable dielectric material. The second low stress dielectric layer 502 preferably has a thickness in the range of 10-50 microns to reduce stress.

Referring to FIG. 5H, the second low stress dielectric layer 502 is coated with a planarizing layer 503. The planarizing layer may be made of the same material as used in the step illustrated in FIG. 5C.

Referring to FIG. 5I, a portion of the planarizing layer 503 is removed, exposing a portion of the second low stress dielectric layer 502. In particular, the level of the planarizing layer 503 is lowered below the top surface of the second low stress dielectric layer 502 over the first and second dies 102, 104. Removal may be accomplished by, for example, by ashing.

Referring to FIG. 5J, the in-process topographic package is planarized to thin a top portion of the exposed second low stress dielectric layer 502. Planarization may accomplished with CMP.

Referring to FIG. 5K, the planarizing layer 503 is removed. Removal may be accomplished by wet chemical etching or ashing.

Referring to FIG. 5L, vias 114 are formed in the first and second low stress dielectric layers 501, 502, such that some of the via holes 114 contact the substrate 100, some of the via holes 114 contact the first dies 102 and some of the via holes 114 contact the second dies 104. The via holes 114 may be formed by any suitable method such as RIE or chemical wet etching.

Referring to FIG. 5M, a barrier layer/adhesion layer 116/117 may deposited such that the barrier layer/adhesion layer 116/117 conformally coats the surfaces of the via holes 114. A metallization layer 118 may then deposited over the barrier layer/adhesion layer 116/117. Any suitable method may be used to conformally deposit the barrier layer/adhesion layer 116/117, such as ALD and CVD. In an embodiment, the barrier layer/adhesion layer 116/117 comprises a separate barrier layer 116 and adhesion layer 117. Suitable materials for the barrier layer 116, include but are not limited to cobalt, ruthenium, tantalum, tantalum nitride, indium oxide, tungsten nitride, and titanium nitride. The adhesion layer 117 may be a seed layer made of the same material as the metallization layer 118.

Referring to FIG. 5N, chemical mechanical polishing is performed to remove excess metallization layer 118 material and excess barrier layer/adhesion layer 116/117 material. The CMP also planarizes the surface of the third dielectric layer 112, thereby forming a surface suitable for hybrid bonding.

Referring to FIG. 5O, any of third dies 120, 122, 124, 126, 128, 130, 134, 138 as discussed in regard to the first embodiment can be hybrid bonded to the bonding dielectric layer 206 and the conductive features 208. Further, as in the first embodiment, one or more fourth dies 142 may be hybrid bonded to the third dies 120, 122, 124, 126, 128, 134 in a fourth device level.

In the present method, a planarizing layer 503 made of a polymer is used in combination with wet etching of low stress dielectric layers 501, 502. Planarizing of a polymer planarizing layer 503 is easier and faster than planarizing the low stress dielectric layers 501, 502. Further, wet etching of the low stress dielectric layers 501, 502 is easier and cheaper than using CMP. Thus, this method may result in cheaper in cheaper packages.

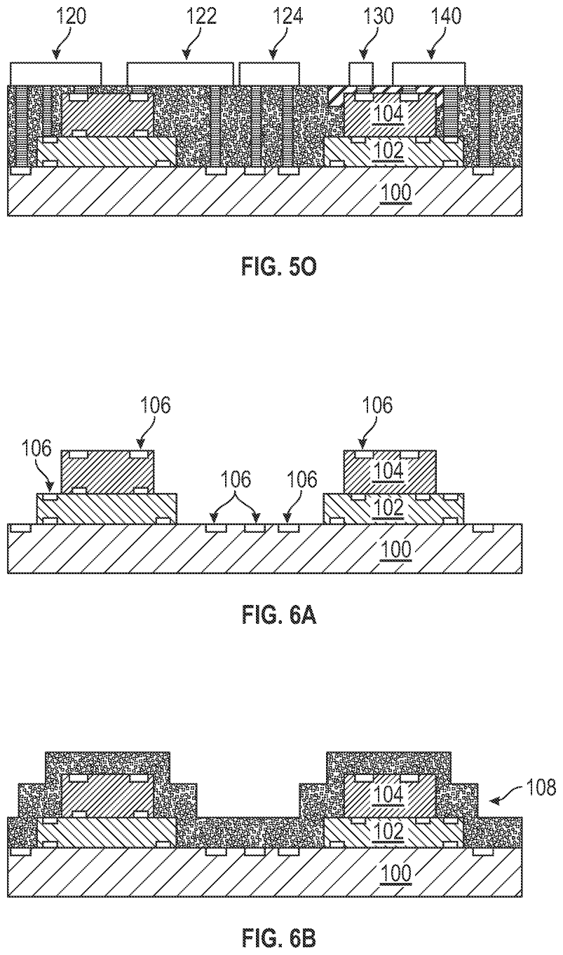

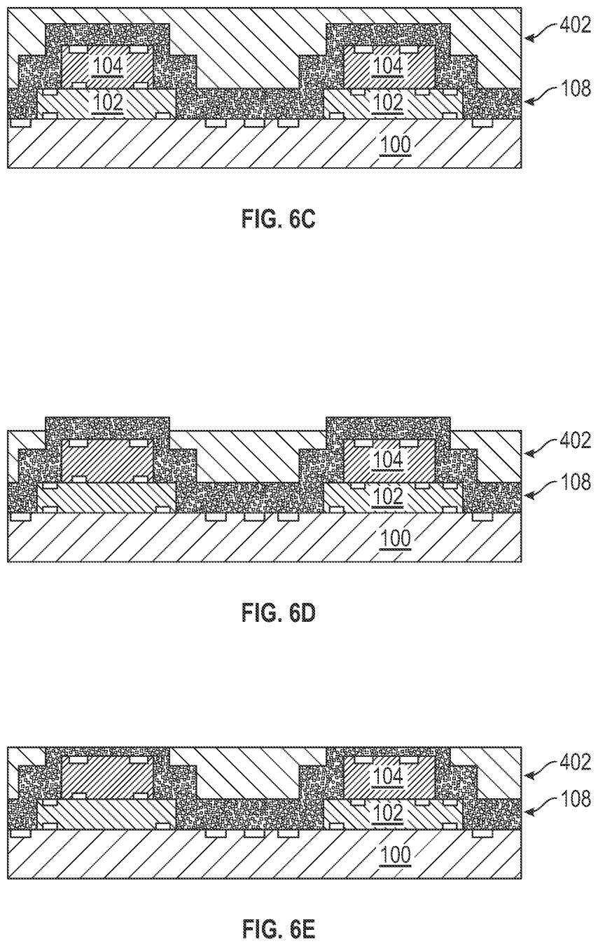

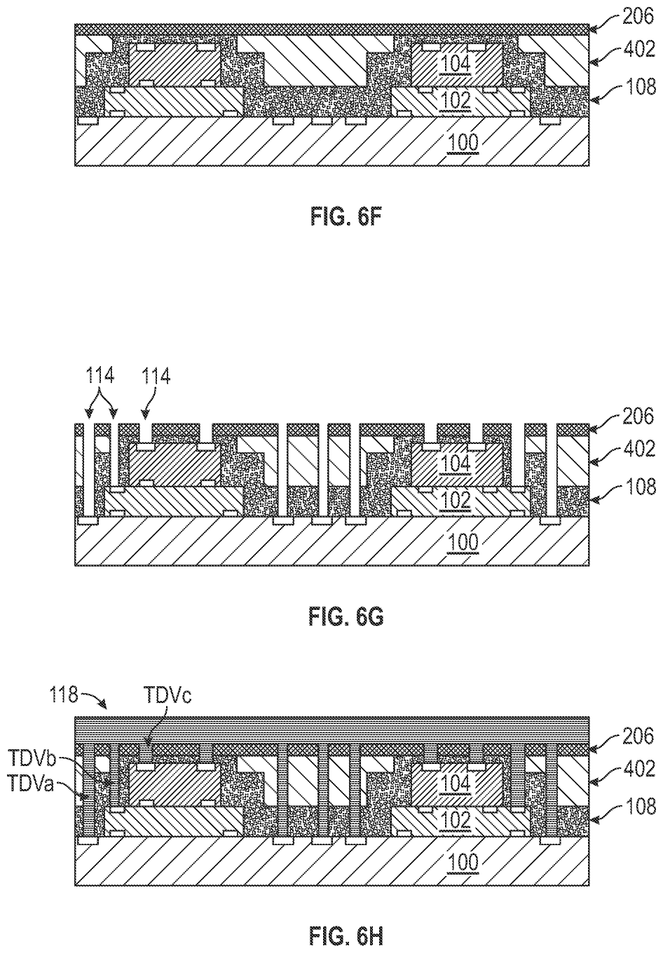

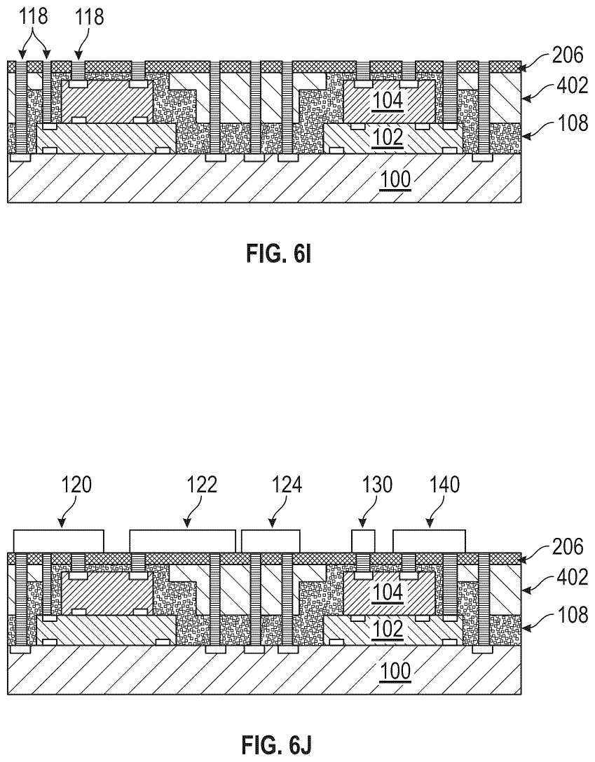

FIGS. 6A-6K schematically illustrate cross-sectional views of a method of making example topographic packages according to some embodiments of the disclosed technology. This embodiment may be referred to as a mixed dielectric coating in topography method. In regards to FIG. 6A, similar to the embodiments discussed above, a substrate 100 may be provided having first and second dies 102, 104 hybrid bonded thereon. Further, as illustrated in FIG. 6A, the first and second dies 102, 104 may have contact pads 106 located on the front side, the back side, or both the front and back sides of the first and second dies 102, 104.

Referring to FIG. 6B, a first dielectric layer 108 may be deposited over the substrate 100, the first dies 102 and the second dies 104. The first dielectric layer 108 may be a silicon oxide SiO₂, silicon nitride Si₃N₄, silicon oxynitride SiOₓN_{y}, or any other suitable dielectric material. Inn this embodiment, the first dielectric layer 108 has a thickness in the range of 1-5 microns.

Referring to FIG. 6C, a organic layer 402 may be deposited over the first dielectric layer 108. The organic layer 402 may comprises a dielectric material such as a resin, polyimide or any other suitable organic dielectric material.

Referring to FIG. 6D, a portion of the organic layer 402 is removed, exposing a portion of the first dielectric layer 108. In particular, the level of the organic layer 402 is lowered below the top surface of the first dielectric layer 108 over the first and second dies 102, 104. Removal may be accomplished by, for example, by ashing.

Referring to FIG. 6E, the exposed portion of the first dielectric layer 108 is thinned. Thinning may be accomplished, for example by wet etching.

Referring to FIG. 6F, a bonding dielectric layer 206 may be deposited over the exposed first dielectric layer 108 and the organic layer 402. The bonding dielectric layer 206 may be silicon oxide SiO₂, silicon nitride Si3N4, silicon oxynitride SiOxNy, or any other suitable dielectric material.

Referring to FIG. 6G, via holes 114 are formed in the bonding dielectric layer 206, first dielectric layer 108 and the organic layer 402 such that some of the via holes 114 contact the substrate 100, some of the via holes 114 contact the first dies 102 and some of the via holes 114 contact the second dies 104. The via holes 114 may be formed by any suitable method such as RIE or chemical wet etching.

Referring to FIG. 6H, a barrier layer/adhesion layer 116/117 is deposited such that the barrier layer/adhesion layer 116/117 conformally coats the surfaces of the via holes 114. A metallization layer 118 is then deposited over the barrier layer/adhesion layer 116/117. Any suitable method may be used to conformally deposit the barrier layer/adhesion layer 116/117, such as ALD and CVD. In an embodiment, the barrier layer/adhesion layer 116/117 comprises a separate barrier layer 116 and adhesion layer 117. Suitable materials for the barrier layer 116, include but are not limited to cobalt, ruthenium, tantalum, tantalum nitride, indium oxide, tungsten nitride, and titanium nitride. The adhesion layer 117 may be a seed layer made of the same material as the metallization layer 118.

Referring to FIG. 6I, chemical mechanical polishing is performed to remove excess metallization layer 118 material and excess barrier layer/adhesion layer 116/117 material. The CMP also planarizes the surface of the bonding dielectric layer 206, thereby forming a surface suitable for hybrid bonding.

Referring to FIG. [6K] 6J, any of third dies 120, 122, 124, 126, 128, 130, 134, 138 as discussed in regard to the first embodiment can be hybrid bonded to the bonding dielectric layer 206 and the conductive features 208. Further, as in the first embodiment, one or more fourth dies 142 may be hybrid bonded to the third dies 120, 122, 124, 126, 128, 134 in a fourth device level.

The present embodiment method includes deposition of a standard dielectric layer 108 and organic layer 402. Processing of the organic layer 402 is easier and cheaper than processing than the conventional methods of forming topographic packages.

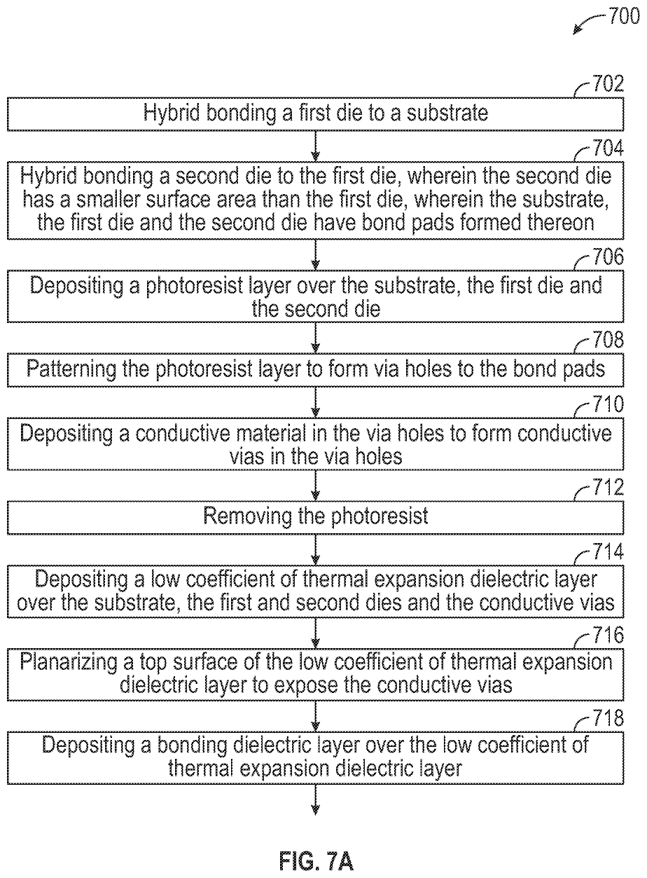

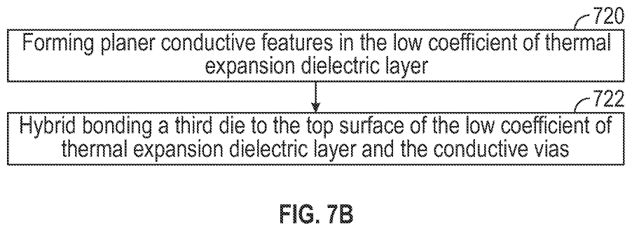

FIGS. 7A and 7B are process flow diagram illustrating a method 700 of making a topographic package in accordance with some embodiments. Referring to step 702, a first die 102 is hybrid bonded to a substrate 100. Referring to step 704, second die 104 is hybrid bonded to the first die 102, wherein the second die 104 has a smaller surface area than the first die 102, wherein the substrate 100, the first die 102 and the second die 104 have contact pads 106 formed thereon. Referring to step 706, a photoresist layer 202 is deposited over the substrate 100, the first die 102 and the second die 104. Referring to step 708, the photoresist layer 202 is patterned to form via holes 114 to the contact pads 106. Referring to step 710, a conductive material is deposited in the via holes 114 to form conductive vias 118 in the via holes 114. Referring to step 712, the photoresist layer 102 is removed. Referring to step 714, a low CTE dielectric layer 204 is deposited over the substrate 100, the first and second dies 102, 104 and the conductive vias 118. Referring to step 716, a top surface of the low coefficient of thermal expansion dielectric layer 204 is planarized to expose the conductive vias 118. Referring to step 718, a bonding dielectric layer 206 is deposited over the low CTE dielectric layer 204. Referring to step 720, vias 118 208 are formed in the low CTE dielectric layer 204. Referring to step 722, a third die 120, 122, 124, 126, 128, 130, 134, 138 is hybrid bonded to the top surface of the low CTE dielectric layer 204 and the conductive vias 118.

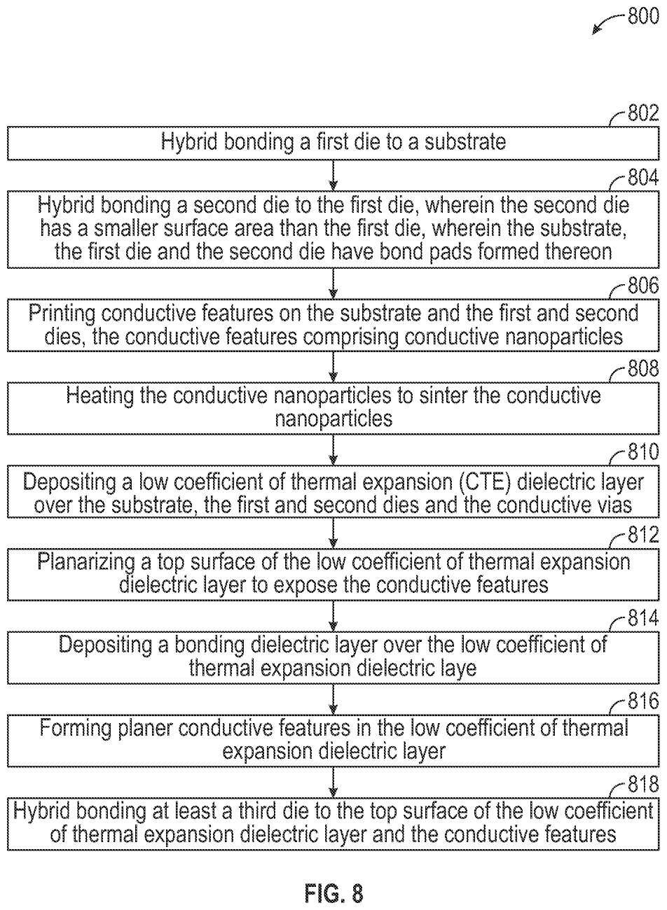

FIG. 8 is a process flow diagram illustrating another method of making example topographic packages according to some embodiments. Referring to step 802, a first die 102 is hybrid bonded to a substrate 100. Referring to step 804, a second die 104 is hybrid bonded to the first die 102, wherein the second die 104 has a smaller surface area than the first die 102, wherein the substrate 100, the first die 102 and the second die 104 have contact pads 106 formed thereon. Referring to step 806, vias 118 are printed on the substrate 100 and the first and second dies 102, 104, the vias 118 comprising conductive nanoparticles. Referring to step 808, the conductive nanoparticles are heated to sinter the conductive nanoparticles. Referring to step 810, a low CTE dielectric layer 204 is deposited over the substrate 100, the first and second dies 102, 104 and the vias 118. Referring to step 812, a top surface of the low CTE dielectric layer 204 is planarized to expose the vias 118. Referring to step 814, a bonding dielectric layer 206 is deposited over the low CTE dielectric layer 204. Referring to step 816, vias 118 are formed in the low CTE dielectric layer 204. Referring to step 818, at least a third die 120, 122, 124, 126, 128, 130, 134, 138 is hybrid bonded to the top surface of the low CTE dielectric layer 204 and the conductive features.

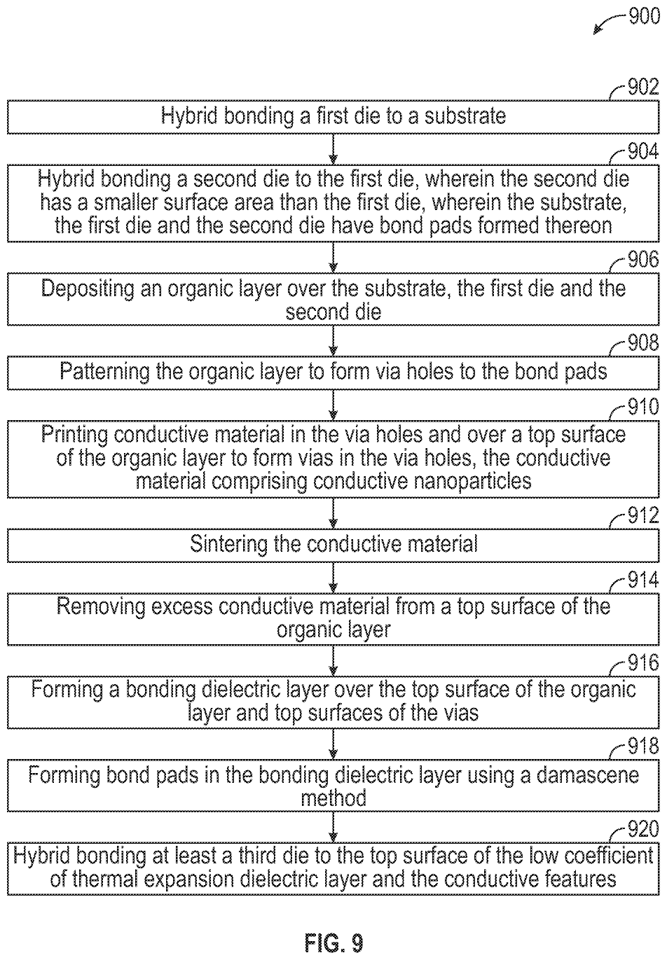

FIG. 9 is a process flow diagram illustrating another method of making example topographic packages according to some embodiments. Referring to step 902, a first die 102 is hybrid bonded to a substrate 100. Referring to step 904, a second die 104 is hybrid bonded to the first die 102, wherein the second die 104 has a smaller surface area than the first die 102 and wherein the substrate 100, the first die 102 and the second die 104 have contact pads 106 formed thereon. Referring to step 906, an organic layer 402 is deposited over the substrate 100, the first die 102 and the second die 104. Referring to step 908, the organic layer 402 is patterned to form via holes 114 to the contact pads 106. Referring to step 910, conductive material is printed in the via holes 114 and over a top surface of the organic layer 402 to form vias in the via holes, the conductive material comprising conductive nanoparticles. Referring to step 912, the conductive material is sintered. Referring to step 914, excess conductive material is removed from a top surface of the organic layer 402. Referring to step 916, a bonding dielectric layer 206 is formed over the top surface of the organic layer 402 and top surfaces of the vias 118. Referring to step 918, contact pads 106 are formed in the bonding dielectric layer 206 using a damascene method. Referring to step 920, at least a third die 120, 122, 124, 126, 128, 130, 134, 138 is hybrid bonded to the prepared top surface of the low CTE dielectric layer 204 and the vias 118.

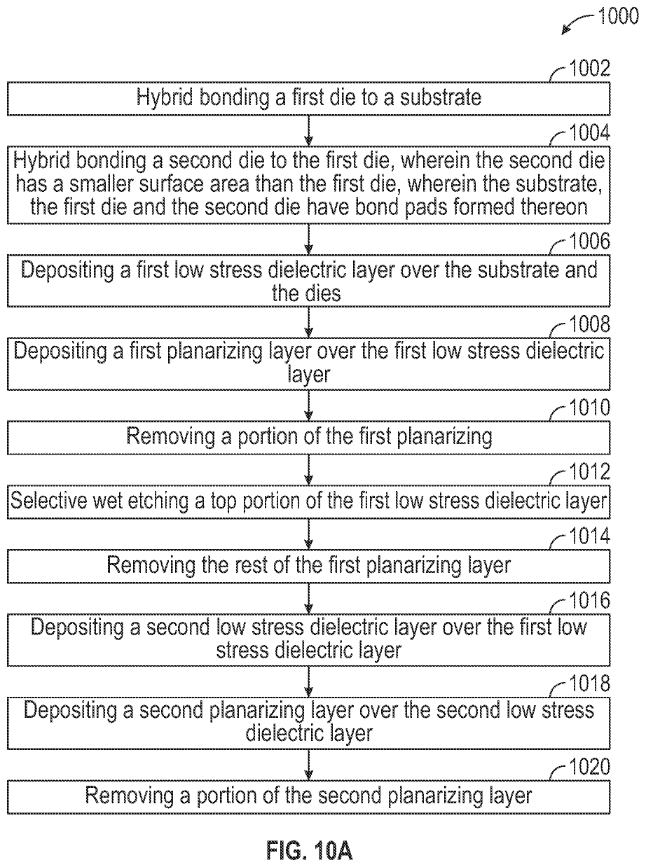

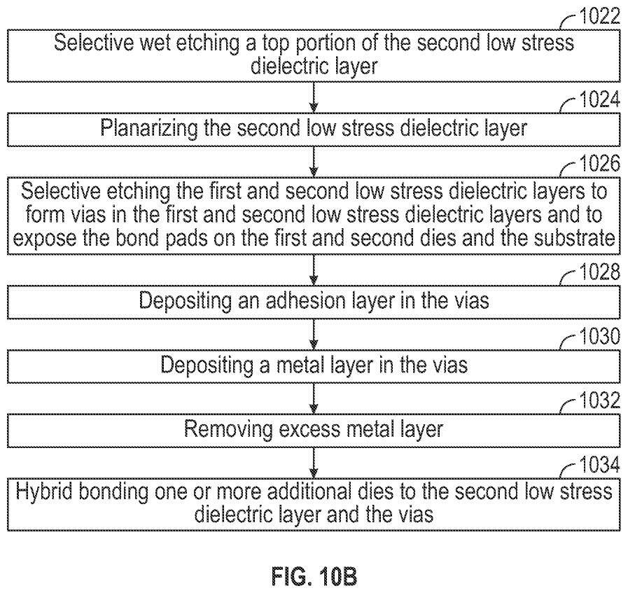

FIGS. 10A and 10B are a process flow diagram illustrating another method of making example topographic packages according to some embodiments. Referring to step 1002, a first die 102 is hybrid bonded to a substrate 100. Referring to step 1004, a second die 104 is hybrid bonded to the first die 102, wherein the second die 104 has a smaller surface area than the first die 102 and wherein the substrate 100, the first die 102 and the second die 104 have contact pads 106 formed thereon. Referring to step 1006, a first low stress dielectric layer 501 is deposited over the substrate 100 and the first and second dies 102, 104. Referring to step 1008, a first planarizing layer 503 is deposited over the first low stress dielectric layer 501. Referring to step 1010, a portion of the first planarizing layer 503 is removed. Referring to step 1012, a top portion of the first low stress dielectric layer 501 is selective wet etched. Referring to step 1014, the rest of the first planarizing layer 503 is removed. Referring to step 1016, a second low stress dielectric layer 502 is deposited over the first low stress dielectric layer 501. Referring to step 1018, a second planarizing layer 503 is deposited over the second low stress dielectric layer 502. Referring to step 1020, a portion of the second planarizing layer 503 is removed. Referring to step 1022, a top portion of the second low stress dielectric layer 502 is selective wet etched. Referring to step 1024, the second low stress dielectric layer 502 is planarized. Referring to step 1026, the first and second low stress dielectric layers 501, 502 are selectively etched to form via holes 114 in the first and second low stress dielectric layers 501, 502 and to expose the contact pads 106 on the first and second dies 102, 104 and the substrate 100. Referring to step 1028, an adhesion layer 116/117 is deposited in the via holes 114. Referring to step 1030, a metal layer 118 in the via holes 114 is deposited. Referring to step 1032, excess metal layer 118 is removed. Referring to step 1034, one or more additional dies are hybrid bonded to the prepared bonding surface of second low dielectric layer 502 and the vias 118.

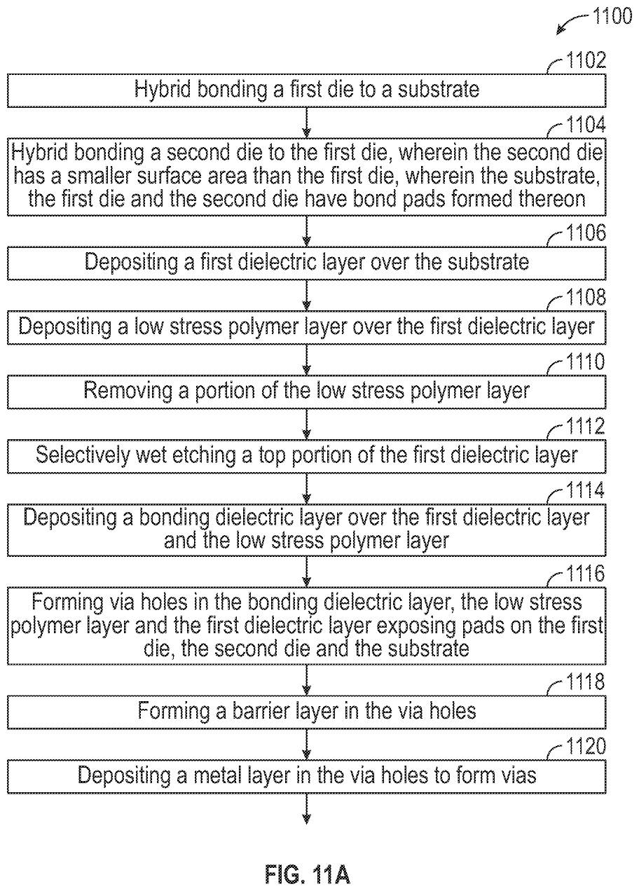

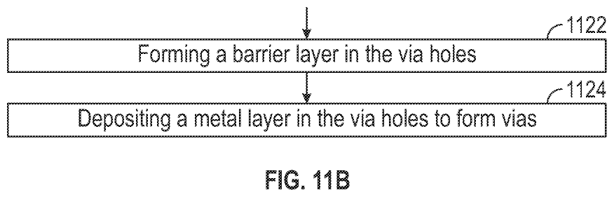

FIGS. 11A and 11B are a process flow diagram illustrating another method of making example topographic packages according to some embodiments. Referring to step 1102, a first die 102 is hybrid bonded to a substrate 100. Referring to step 1104, a second die 104 is hybrid bonded to the first die 102, wherein the second die 104 has a smaller surface area than the first die 102 and wherein the substrate 100, the first die 102 and the second die 104 have contact pads 106 formed thereon. Referring to step 1106, a first dielectric layer 108 is deposited over the substrate 100. Referring to step 1108, a low stress polymer layer 402 is deposited over the first dielectric layer 108. Referring to step 1110, a portion of the low stress polymer layer 402 is removed. Referring to step 1112, a top portion of the first dielectric layer 108 is selectively wet etched. Referring to step 1114, a bonding dielectric layer 206 is deposited over the first dielectric layer 108 and the low stress polymer layer 402. Referring to step 1116, via holes 114 are formed in the bonding dielectric layer 206, the low stress polymer layer 402 and the first dielectric layer 108 exposing pads on the first die 102, the second die 104 and the substrate 100. Referring to step 1118, a barrier layer is formed in the via holes 114. Referring to step 1120, a metal layer is deposited in the via holes 114 to form vias 118. Referring to step 1122, excess metal is removed. Referring to step 1124, a third die 120, 122, 124, 126, 128, 130, 134, 138 is hybrid bonded to a top surface of the bonding dielectric layer 206 and a top surface of the vias 118.

In some embodiments, the conductive via 114 may comprise of an incompletely filled via cavity, for example a cavity containing a conformally filed conductive layer. After the planarization and cleaning step, the coated dielectric layer 206 may line the interior of the incompletely filed via and may plug the opening of the via. In practice, it is preferable to planarize the coated dielectric layer 206 before patterning the dielectric 206 to form cavities for conductive features 208. In some embodiments, the formed dielectric layer 206 may comprise of a redistribution layer formed over the top surface of dies 104. In some embodiments the conductive features of the redistribution layer are connected to the vias 118 of this invention.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. A method of making a electronic component comprising:
hybrid bonding a first die to a substrate;
hybrid bonding a second die to the first die, wherein the second die has a smaller surface area than the first die, wherein the substrate, the first die and the second die have bond pads formed thereon;
forming an insulating material disposed over the substrate and at least partially encapsulating the first and second dies;
direct hybrid bonding a third die bonded to the insulating material; and
forming a first conductor extending through at least a portion of the insulating material to electrically connect the third die and at least one of the first die, the second die, and the substrate.

31. The method of claim 30, wherein the insulating material comprises a polymer, an oxide or a layer of oxide and a layer of polymer.

32. The method of claim 30, further comprising forming additional conductors to connect the third die to at least one of the first die, the second die, or the substrate.

33. The method of claim 30, wherein forming a first conductor comprises printing nanoparticles.

34. The method of claim 30, wherein forming an insulating material comprises depositing a polymer with dielectric nanoparticles embedded therein.

35. A method of making a electronic component comprising:
direct hybrid bonding a first die to a substrate;
direct hybrid bonding a second die to the first die, wherein the second die has a smaller surface area than the first die, wherein the substrate, the first die and the second die have bond pads formed thereon;
printing vias on the substrate and the first and second dies, the vias comprising conductive nanoparticles;
heating the conductive nanoparticles to sinter the conductive nanoparticles;
depositing a low coefficient of thermal expansion (CTE) dielectric layer over the substrate, the first and second dies and the vias;
planarizing a top surface of the low CTE dielectric layer to expose the vias;
depositing a bonding dielectric layer over the low CTE layer;
forming conductive features in the low CTE dielectric layer; and
direct hybrid bonding at least a third die to the top surface of the low CTE dielectric layer and the conductive features.

36. The method of claim 35, wherein the nanoparticles comprise copper, silver, nickel or alloys thereof.

37. The method of claim 35, wherein printing conductive features comprises using a 3D printer.

38. The method of claim 35, wherein the low CTE dielectric layer comprises particles embedded in a polymer.

39. The method of claim 38, wherein the low CTE dielectric layer comprises SiO₂ particles embedded in a resin or polyimide matrix.

40. The method of claim 38, wherein the bonding dielectric layer comprises silicon oxide SiO₂, silicon nitride Si₃N₄ or silicon oxynitride SiOₓN_{y}.

41. (canceled)

42. (canceled)

43. (canceled)

44. (canceled)

45. (canceled)

46. (canceled)

47. (canceled)

48. (canceled)

49. (canceled)

50. (canceled)

51. (canceled)

52. (canceled)

53. (canceled)

54. (canceled)

55. (canceled)

56. (canceled)

57. A method of making a electronic component comprising:
direct hybrid bonding a first die to a substrate
direct hybrid bonding a second die to the first die, wherein the second die has a smaller surface area than the first die, wherein the substrate, the first die and the second die have bond pads formed thereon;
depositing a first dielectric layer over the substrate;
depositing a low stress polymer layer over the first dielectric layer;
removing a portion of the low stress polymer layer;
selectively wet etching a top portion of the first dielectric layer;
depositing a bonding dielectric layer over the first dielectric layer and the low stress polymer layer;
forming via holes in the bonding dielectric layer, the low stress polymer layer and the first dielectric layer exposing pads on the first die, the second die and the substrate;
forming a barrier layer in the via holes;
depositing a metal layer in the via holes to form vias;
removing excess metal; and
direct hybrid bonding a third die to a top surface of the bonding dielectric layer and a top surface of the vias.

58. The method of claim 57, wherein the first dielectric layer has a thickness of 1-5 microns.

59. The method of claim 57, wherein the barrier layer is also an adhesion layer.

60. The method of claim 57, wherein the metal in the vias is deposited by electroplating, electroless plating, atomic layer deposition (ALD) or chemical vapor deposition (CVD).

61. The method of claim 57, wherein the low stress polymer layer comprises a polyimide.

62. The method of claim 57, wherein removing a portion of the low stress polymer layer is performed in an oxygen plasma.

63. The method of claim 57, further comprising forming a top bond pad on the top surface of the bonding dielectric layer.

64. The method of claim 57, further comprising forming a upper bond pad on a top surface of the bonding dielectric layer, the upper bond pad configured to provide electricity to the electronic component.

65. The method of claim 57, further comprising direct hybrid bonding a fourth die to a top surface of the bonding dielectric layer and a top surface of the vias.
